(19) United States
(12) Patent Application Publication
(10) Pub. No.: US 2023/0245860 A1
(43) Pub. Date: Aug. 3, 2023

(54) DIFFUSING PLATE, ETCHING EQUIPMENT AND HOLE CONFIGURING METHOD FOR DIFFUSING PLATE

(71) Applicant: LINCO TECHNOLOGY CO., LTD., Taichung City (TW)

(72) Inventors: Yi-Yuan HUANG, Taichung City (TW); Cheng-Yu TSAO, Taichung City (TW); Cheng-Sheng LIN, Taichung City (TW); Tsung-Wei CHANG, Taichung City (TW); Yi-Cheng LIU, Taichung City (TW)

(21) Appl. No.: 18/299,079

(22) Filed: Apr. 12, 2023

Related U.S. Application Data
(63) Continuation-in-part of application No. 17/168,206, filed on Feb. 5, 2021.

(51) Int. Cl. H01J 37/32

(52) U.S. Cl. CPC H01J 37/3244; H01J 37/32715; H01J 37/32807; H01J 2237/3341

(57) ABSTRACT

A diffusing plate includes a plate body including a rectangular hole-configuring region, a plurality of holes arranged in the rectangular hole-configuring region and arranged concentrically to form a first to an N-th rectangular patterns from an inside to an outside sequentially. Scales of the first to the N-th rectangular patterns are incrementally increased, and N is a positive integer. One portion of the holes are located in an area near a center of the rectangular hole-configuring region, another portion of the holes are located in four corner areas of the rectangular hole-configuring region, each of the holes has a diameter, and the diameter of the one portion of the holes is smaller than the diameter of the another portion of the holes.

### RELATED APPLICATIONS

This application is a Continuation-in-part of U.S. application Ser. No. 17/168,206, filed on Feb. 5, 2021, the entirety of which is incorporated by reference herein.

### BACKGROUND

### Technical Field

The present disclosure relates to a diffusing plate, a processing equipment, and a hole configuring method for the diffusing plate, and in particular to a diffusing plate, an etching equipment and a hole configuring method for the diffusing plate.

### Description of Related Art

The International Technology Roadmap for Semiconductors (ITRS) pointed out that the traditional CMOS process is close to its limit. In response to the continuous growth of industry and the reduction of the cost per unit function, new device types, new packaging architecture, and new materials are required. Particularly, as Moore's Law approaches its end, the development of the semiconductor industry may switch focus to heterogeneous integration. As a result, system in package (SiP) technology would become a critical solution that balances both performance diversity and cost. In response to this new architecture, embedded devices that include printed circuits, thinner wafers, and active/passive may be vigorously developed. The fabrication tools/apparatus and process materials used in advanced packaging may also undergo rapid changes to meet the demand of the new architecture. In the next 15 years, the focus of the heterogeneous integration may be placed on assembly, packaging, testing, and interconnection technologies.

Advanced packaging technology such as embedded die in substrate (EDS), embedded passive in substrate (EPS), fan-out panel level packaging (FOPLP) and redistribution layer (RDL), or the advanced display technology using Micro-LED or Mini-LED often calls for the use of composite substrate having dielectric insulating materials, semiconductor element chips, and metal wirings embedded therein. In some fabrication processes where EDS, EPS, or FOPLP packaging techniques are applied, the singulated semiconductor components, passive components or metal bumps (e.g., copper pillar) are arranged and buried in a large organic insulating material (such as molding compound, Copper Clad Laminate (CCL), Ajinomoto Build-up Film (ABF), or dry film photoresist); then unnecessary organic insulating material is thinned by grinding to selectively expose chip components or metal wires. However, during the grinding process, the chip or component may be damaged by external stresses.

With advances in the semiconductor industry, plasma processes are widely adapted, for example being adapted in removing unnecessary substrates or materials. In such usage, the substrate or the material may be disposed in a vacuumed chamber, then a processing gas is decomposed by a plasma source so as to generate free radicals, and the free radicals may spread to a surface of the substrate or the material uniformly to conduct a chemical dry etching. An electric field may also be generated in the vacuumed chamber, and the plasma may impact the surface of the substrate or the material in a specific direction to conduct a physical dry etching, thereby achieving goals of thinning, removing oxide layer, and planarization.

Generally, the aforementioned etching process may include a diffusing plate with a plurality of holes being disposed in a chamber, and a gas inlet. For example, in the chemical dry etching, the processing gas may be diffused from the holes of the diffusing plate toward different positions in the chamber to conduct etching on the to-be-etched substrate.

However, the gas inlet is often located in a center position of the chamber and corresponds to a center of the substrate, causing the density of the processing gas to be lower in the periphery of the substrate. In addition, the fan-out packaging is mainly used in the wafer-level packaging (WLP), and holes of the diffusing plate applied thereto are arranged concentrically to form a plurality of concentric circular patterns. As applied in panel-level packaging (PLP), since the shape of the substrate changes from circular to rectangular and the scales thereof are severely increased, if the holes are still arranged in the concentric circular patterns as shown in FIG. 20 which shows a front view of a diffusing plate P1 according to the prior art, non-uniformity of the processing gas during diffusion may occur as shown in FIG. 21 which shows a CF₄ (gas) density distribution on a substrate at different stages of the diffusion process specified by the degree of CF₄ saturation of the substrate as the diffusing plate P1 of FIG. 20 diffusing CF₄, resulting in poor yield of etching.

Hence, developing a diffusing plate to increase the diffusing uniformity of the processing gas becomes a much pursued goal in the industry.

### SUMMARY

According to one aspect of the present disclosure, a diffusing plate includes a plate body including a rectangular hole-configuring region, a plurality of holes arranged in the rectangular hole-configuring region and arranged concentrically to form a first to an N-th rectangular patterns from an inside to an outside sequentially. Scales of the first to the N-th rectangular patterns are incrementally increased, and N is a positive integer. One portion of the holes are located in an area near a center of the rectangular hole-configuring region, another portion of the holes are located in four corner areas of the rectangular hole-configuring region, each of the holes has a diameter, and the diameter of the one portion of the holes is smaller than the diameter of the another portion of the holes.

According to another aspect of the present disclosure, an etching equipment includes a chamber, a gas inlet communicated with the chamber and configured for providing a processing gas, and the aforementioned diffusing plate is disposed in the chamber and located under the gas inlet.

According to still another aspect of the present disclosure, a hole configuring method for a diffusing plate includes a hole-configuring region designing step and a hole configuring step. In the hole-configuring region designing step, a rectangular hole-configuring region of a plate body of the diffusing plate is defined. In the hole configuring step, positions of a plurality of holes are arranged in the rectangular hole-configuring region. The holes are arranged concentrically to form a first to an N-th rectangular patterns from an inside to an outside sequentially, scales of the first to the N-th rectangular patterns are incrementally increased, and N is a positive integer. One portion of the holes are located in an area near a center of the rectangular hole-configuring region, and another portion of the holes are located in four corner areas of the rectangular hole-configuring region. Each of the holes has a diameter, and the diameter of the one portion of the holes is smaller than the diameter of the another portion of the holes. ΔSᵢ represents a side-length difference between an i-th rectangular pattern of the first to the N-th rectangular patterns and a neighboring one of the first to the N-th rectangular patterns adjacent thereto, and ΔSᵢ is positive. CIᵢ represents a circumferential hole distance between one of the holes that is located in the i-th rectangular pattern and a neighboring one of the holes adjacent thereto along a side-length direction of the i-th rectangular pattern, i is an integer index representing each of the first to the N-th rectangular patterns and ranged between 1 to N, and ΔS₁ is equal to a side-length of the first rectangular pattern. The hole configuring step includes defining an actual circumferential hole distance upper-limit range and an actual circumferential hole distance lower-limit range, partitioning the first to the N-th rectangular patterns into a plurality of groups, each of the groups containing an integer dⱼ of neighboring rectangular patterns, staring from an i_{min,j}-th rectangular pattern to an i_{max,j}-th rectangular pattern, wherein i_{max,j}=i_{min,j}+dⱼ−1, and configuring the circumferential hole distance CIᵢ of the i_{min,j}-th rectangular patterns of each of the groups to fall within the actual circumferential hole distance lower-limit range, configuring the circumferential hole distance CIᵢ of the i_{max,j}-th rectangular pattern of each of the groups to fall within the actual circumferential hole distance upper-limit range, configuring the circumferential hole distances CIᵢ of the i_{min,j}-th to the i_{max,j}-th rectangular patterns of each of the groups to be monotonously increased as the corresponding integer index i increases. An i_{max,j}+1-th rectangular pattern belongs to another one of the groups adjacent thereto, and the circumferential hole distance of the i_{max,j}+1-th rectangular pattern is smaller than the circumferential hole distance of the i_{max,j}-th rectangular pattern.

### BRIEF DESCRIPTION OF THE DRAWINGS

The patent or application file contains at least one drawing executed in color. Copies of this patent or patent application publication with color drawing(s) will be provided by Office upon request and payment of the necessary fee. The invention can be more fully understood by reading the following detailed description of the embodiment, with reference made to the accompanying drawings as follows:

FIG. 1 shows a schematic cross-sectional view of an etching equipment according to some embodiments of the present disclosure.

FIG. 2 shows an enlarged regional view of an etching equipment according to some embodiments of the present disclosure.

FIG. 3A shows an isometric exploded illustration of components for a substrate manufacturing equipment according to some embodiments of the present disclosure.

FIGS. 3B and 3C respectively show a three-dimensional schematic diagram of a substrate support according to some embodiments of the present disclosure.

FIG. 4 shows a schematic illustration of a bottom face of a plasma intake wall according to some embodiments of the present disclosure.

FIG. 5 shows a schematic cross-sectional view of a plasma intake wall according to some embodiments of the present disclosure.

FIG. 6 shows a schematic regional cross-sectional view of a plasma intake wall according to some embodiments of the present disclosure.

FIG. 7 shows experimental test data of an etching equipment in accordance with some embodiments of the present disclosure.

FIG. 8 shows a schematic top view of an etching equipment according to some embodiments of the present disclosure.

FIG. 9 shows a front view of a diffusing plate according to some embodiments of the present disclosure.

FIG. 10 shows a partial enlarged front view of a diffusing plate according to some embodiments of the present disclosure.

FIG. 11 shows a front view of a diffusing plate according to some embodiments of the present disclosure.

FIG. 12 shows a block flow chart of a hole configuring method for a diffusing plate according to some embodiments of the present disclosure.

FIG. 13 shows a chart of circumferential hole distances and side-lengths of a hole configuring method for a diffusing plate according to some embodiments of the present disclosure.

FIG. 14 shows a relation between the density and time as a diffusing plate of a first example of the present disclosure and a diffusing plate of a prior art diffusing CF₄.

FIG. 15 shows a relation between a CF₄ non-uniformity and the time as the diffusing plate of the first example of the present disclosure and the diffusing plate of the prior art diffusing CF₄.

FIG. 16 shows a relation between a CF₄ non-uniformity and the degree of CF₄ saturation as the diffusing plate of the first example of the present disclosure and the diffusing plate of the prior art diffusing CF₄.

FIG. 17 shows a CF₄ diffusing status and the degree of CF₄ saturation as the diffusing plate of the first example diffusing CF₄.

FIG. 18 shows CF₄ non-uniformities as functions of the degree of CF₄ saturation as the diffusing plates of a second example, a third example and a fourth example of the present disclosure and a diffusing plate of a first comparison example diffusing CF₄.

FIG. 19 shows a CF₄ diffusing status and the degree of CF₄ saturation as the diffusing plate of the second example, the third example, the fourth example and the first comparison example diffusing CF₄.

FIG. 20 shows a front view of a diffusing plate according to the prior art.

FIG. 21 shows a CF₄ (gas) density distribution on a substrate at different stages of the diffusion process specified by the degree of CF₄ saturation of the substrate as the diffusing plate of FIG. 20 diffusing CF₄.

It is to be noted, however, that the appended drawings illustrate only exemplary embodiments of this disclosure and are therefore not to be considered limiting of its scope, for the disclosure may admit to other equally effective embodiments.

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of layers, regions and/or structural elements may be reduced or exaggerated for clarity. The use of similar or identical reference numbers in the various drawings is intended to indicate the presence of a similar or identical element or feature.

### DETAILED DESCRIPTION

The present disclosure will now be described more fully hereinafter with reference to the accompanying drawings, in which exemplary embodiments of the disclosure are shown. This disclosure may, however, be embodied in many different forms and should not be construed as limited to the exemplary embodiments set forth herein. Rather, these exemplary embodiments are provided so that this disclosure will be thorough and complete, and will fully convey the scope of the disclosure to those skilled in the art. Like reference numerals refer to like elements throughout.

The terminology used herein is for the purpose of describing particular exemplary embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” or “includes” and/or “including” or “has” and/or “having” when used herein, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

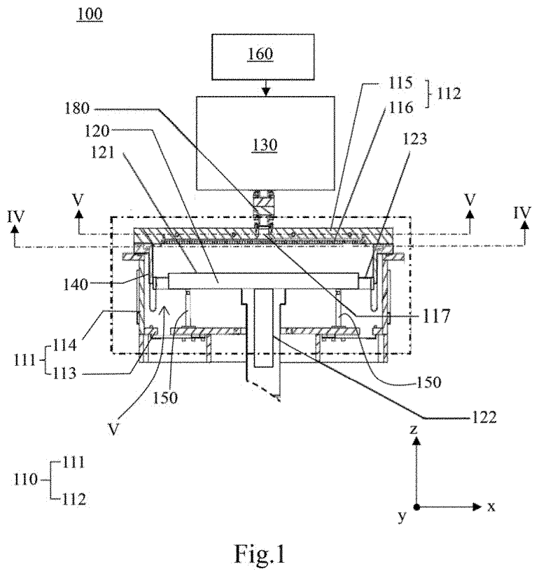

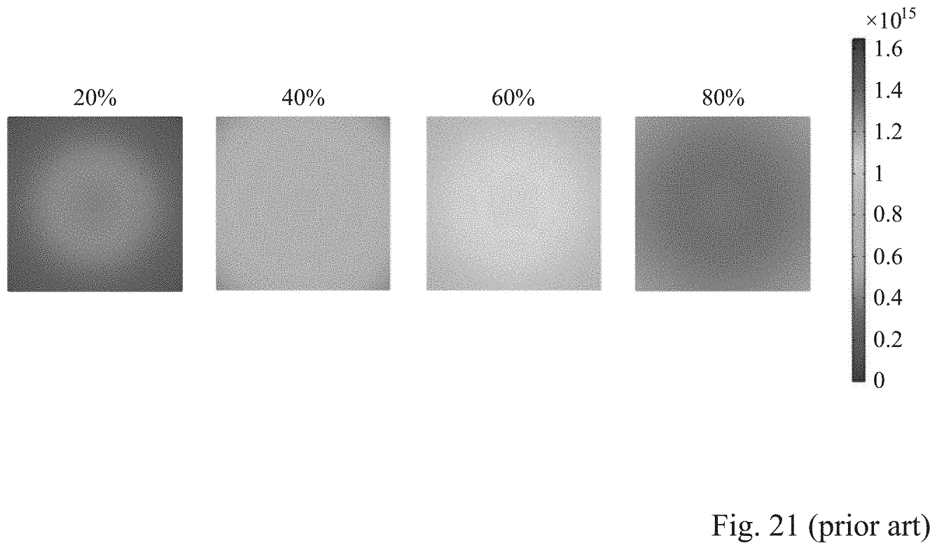

Exemplary embodiments will be described in conjunction with the drawings from FIGS. 1 to 21. The present disclosure will be described in detail with reference to the accompanying drawings, in which the depicted elements are not necessarily shown to scale, and through several views, the same or similar reference signs may be used to denote the same or similar elements.

FIG. 1 shows a schematic cross-sectional view of an etching equipment 100 according to some embodiments of the present disclosure. For simplicity and clarity of description, some details/sub-components of the exemplary system are not clearly marked/shown in this figure.

The etching equipment 100 can be operated to perform many processes that apply plasma, e.g., using plasma to etch and/or thin down dielectric insulating materials. Take EDS, EPS, or FOPLP packaging applications for example, some applications call for the thinning of dielectric insulating materials (such as Epoxy Molding Compound (EMC) and ABF (Ajinomoto Build-up Film, ABF) insulating film) to achieve, e.g., surface flattening/planarization and/or die exposure. In addition to the above-mentioned thinning process of insulating materials, the etching equipment 100 may also be utilized for, e.g., removal of surface organic or inorganic residues, ashing process, photoresist stripping, hydrophilic and hydrophobic surface treatment processes (such as modification and surface cleaning), descum or desmear, etching treatment after laser treatment, ashing treatment of photoresist, etching treatment of titanium film, SiO₂ film or Si₃N₄ film, and metal oxide film plasma reduction treatment.

The exemplary etching equipment 100 includes a processing chamber 110 or chamber 110, a substrate support 120, and a remote plasma source (RPS) 130. The processing chamber 110 defines an internal space V configured to receive a processing workpiece (now shown in the instant illustration). In some embodiments, the processing workpiece may be a substantially planar object generally referred to as a substrate, which provides mechanical support to subsequently formed electrical components formed thereon. In some applications, the substrate may be a semiconductor wafer. In some applications, e.g., panel-level processes such as FOPLP packaging applications or advanced IC board with thin circuit traces, the substrate may include large size glass substrates, epoxy molding compounds, copper clad laminates, or coreless substrates. The exemplary processing chamber 110 includes a base 111 and a plasma intake wall 112. The base 111 has a bottom wall 113 and a side wall 114 to define the internal space V. The plasma intake wall 112 is configured to cooperatively establish a closure with the base 111 and receive output from the remote plasma source 130. In some embodiments, the output from the remote plasma source 130 may be free radicals that are electrically neutral. In some embodiments, the etching equipment 100 further includes a baffle ring 140. The baffle ring 140 is arranged to situate between the base 111 and the plasma intake wall 112.

The substrate support/stage 120 or substrate carrier 120 is elevatably arranged in the internal space V of the processing chamber 110 and has a substrate supporting surface 121 facing the plasma intake wall 112. The substrate support 120 (e.g., pedestal) is configured to support the substrate on a top surface thereof (e.g., the substrate supporting surface 121) during the manufacturing process. In some embodiments, the apparatus 100 further includes one or more lifting devices coupled to the substrate support 120, and the lifting devices are adapted to move the substrate support 120 at least in a vertical direction (for example, the z-direction) to facilitate substrate loading/unloading operations, and/or to adjust a distance between the substrate and the plasma intake wall 112 (the nozzle member). When the substrate support 120 is lowered, the lifting pin 150, provided in a lower portion of the processing chamber 110, can extend upward to support the substrate to facilitate loading/extraction operation of the workpiece into/out of the chamber. In some embodiments, the substrate support 120 is further provided with a gas passage (e.g., gas extraction/exhaust channel 123). As illustrated in the instant embodiment, the gas exhaust channel 123 is arranged proximate the outer edge region of the substrate support 120, while the lateral edge(s) of the carrier is maintained at a close proximity from a corresponding segment (e.g., the upper half portion) of the inner chamber surface. When an exhaust/extracting device (not shown in the figure) is activated, the by-products (often in micro-particle or gaseous form) can be moved to the space below the substrate support 120 through the gas exhaust channel 123. In some embodiments, the stage is further provided with a positioning ring (or cover ring) arranged around the substrate supporting surface 121 and is located between the substrate supporting surface 121 and the gas exhaust channel 123. In some embodiments, the positioning ring comprises an insulating material, such as Al₂O₃, ZrO₂, Si₃N₄, AlN, machinable ceramics, Quartz, glass, or Teflon.

The plasma intake wall 112 is configured to close the trough-like structure of the base 111, thereby establishing a sealing engagement to form the internal space V of the processing chamber 110. The plasma intake wall 112 is in fluid communication with the remote plasma source 130 through an inlet port 117 or gas inlet 117 over a central region of the substrate support 120, so the outputs from the remote plasma source 130 may be directed and distributed into the chamber 110. In the illustrated embodiment, the plasma intake wall 112 includes a lid 115 and a diffusing plate 116 disposed between the inlet port 117 and the substrate supporting surface 121. The outer periphery of the lid 115 (or referred to as a chamber cover) is configured to establish sealing engagement with the top of the surrounding wall of the base 111. The diffusing plate 116 (e.g., spray head component/spray head/shower head) is configured to uniformly supply output/processing gas from the remote plasma source 130 into the internal space V. The shower head 116 is shown to be arranged in a substantially parallel relationship with respect to the carrying surface of the substrate support 120, which facilitates the uniform distribution of processing gas over a workpiece. Nevertheless, the distribution state of processing gas is affected by various factors, such as the geometric structure of the internal space V, the distance between the diffusing plate 116 and the substrate support 120. In some embodiments, the distance between the diffusing plate 116 and the substrate support 120 is substantially in a range of 10-200 mm, such as 30 or 90 mm. In some embodiments, the diffusing plate 116 and the lid 115 may be made of conductive materials (such as aluminum) and be in electrical communication with each other. The base 111 can also be electrically connected to the diffusing plate 116 and the lid 115 by using a conductive material (such as aluminum).

The etching equipment 100 may also include, or otherwise in connection with, an exhaust/exhaust system (not shown), which is configured to apply a negative pressure to the internal space V (or the process volume) to generate vacuum condition. In some applications, the operating pressure in the chamber may be controlled at about 50-5000 mTorr.

In some applications, the utilization of RPS may allow most of the generated charged particles (e.g., ions and electrons) from the plasma generator to be kept from the processing chamber (such as the internal space V), while granting passage of the electrically neutral free radicals into the processing chamber through the inlet component (such as the plasma intake wall 112). The use of free radicals may enable lowered processing temperature for certain delicate applications. In some applications, when the gas from a gas source 160 reaches sufficient gas flow rate (e.g., several standard liters per minute (SLM)), the dissociation rate of the remote plasma source for the processing gas may reach 95% or more. Thus, in some embodiments, the remote plasma source may also be referred to as a free radical plasma source. For instance, in plasma etching processes, the etching rate over the workpiece is proportional to the density of free radicals in the processing chamber. Because the free radicals generated by the remote plasma source predominately induce chemical reaction over the surface of the substrate, the resulting lowered thermal loading and reduced ion bombardment by using RPS may help to minimize physical damage to the workpiece in a various of applications such as high-speed etching, ashing, desmearing, descum, cleaning, or surface modification/activation treatment operations.

The remote plasma source is configured to receive various gases (for example, from the gas source 160), such as fluorine-containing reactant gas (such as CF₄, CₓF_{y}, SF₆, NF₃, CHF₃ or their mixed gas) and cleaning gas (such as O₂, O₃, H₂O, H₂, He, N₂, Ar or their mixed gas). The addition of N₂ gas may increase plasma density and prolong the lifetime of output gas in free radical form. The gas source 160 may provide the gas at a controlled flow rate. For instance, when the fluorine-containing gas is provided to the remote plasma source, the flow rate may be regulated to be within about 10 to 6000 sccm. For example, in various embodiments, the fluorine-based gas may be provided at a flow rate between about 10 to 3000 sccm, between about 10 to 2000 sccm, or between about 10 to 1000 sccm. Likewise, when the cleaning gas is supplied to the RPS, the flow rate may be controlled between about 10-6000 sccm. For example, in various embodiments, the flow rate of the cleaning gas may be regulated between about 10 to 5000 sccm, about 10 to 4000 sccm, about 10 to 3000 sccm, about 10 to 2000 sccm, or about 10 to 1000 sccm.

The remote plasma source may adopt inductively-coupled plasma source (ICP), capacitively coupled (CCP) remote plasma source, and a microwave remote plasma source (Microwave RPS), or a combination thereof. In an embodiment wherein an inductively coupled remote plasma source (ICP RPS) is used, the driving frequency thereof may be set to about 0.4 to 13.56 MHz. In an embodiment using a very high frequency (VHF) capacitive coupling type remote plasma source, the driving frequency may be set to about 40 to 100 MHz. In an embodiment where a microwave remote plasma source (Microwave RPS) is used, the driving frequency may be set to about 900 to 6000 MHz. In various embodiments that incorporate RPS, the output power may be in the range of about 1-3 kW, 1-6 kW, 1-8 kW, 1-10 kW, or 1-15 kW.

In some operating scenarios, the free radicals from the RPS will generate a recombination reaction (exothermic reaction) in the pipeline (e.g., the passage between to the RPS and the plasma intake) so as to cause elevation of temperature in the pipeline. In some cases, the elevation of temperature is pronounced and may cause excessive wear of the device hardware (e.g., O-ring). In some embodiments, the exemplary device in accordance with the instant disclosure is provided with a cooling mechanism 180. The cooling mechanism 180 may include a liquid-cooled flow channel configured to receive cryogenic fluid (for example, water, other liquids or gases) from a fluid supply system. In some embodiments, the processing apparatus further comprises a valve configured to regulate fluid communication from the RPS to the processing chamber 110. In some embodiments, the cooling mechanism 180 may further include a cooling chip (e.g., thermoelectric cooling module) in thermal contact with the valve body.

In some embodiments, in addition to the first plasma generating device (which includes the remote plasma source 130), the apparatus 100 or the etching equipment 100 may also be provided with a second plasma generating device (e.g., a local/onboard plasma generator) provided in the processing chamber. In terms of hardware configuration, in some embodiments, the substrate support 120 may be configured to be coupled to an electrode member 122 that receives output from a radio frequency (RF) power source. Meanwhile, the shower head component (e.g., the diffusing plate 116) may be configured to be electrically connected (e.g., to the ground), so that the shower head and the substrate support 120 respectively form a pair of opposite electrodes for the onboard/local plasma generator.

In an embodiment of dual plasma source configuration, the remote plasma source may employ one or more of inductively coupled remote plasma source (ICP RPS), capacitively coupled remote plasma source (CCP RPS), and microwave remote plasma source (Microwave RPS). On the other hand, the aforementioned radio frequency plasma source (i.e., the second plasma source) may adopt a capacitive coupling device. The plasma generator incorporated devices may be used to perform material reduction processes such as Reactive-Ion Etching (RIE). Exemplary applications of RIE may include ashing process, photoresist stripping, surface modification, cleaning and activation, descum, desmear, nitrogen/argon-based plasma treatment for copper film to remove surface oxides/fluorides, or for surface roughening applications. In the illustrated embodiment, when RPS (first plasma generator) generates high-density reactive free radicals, high-frequency bias may be concurrently applied to the substrate support (second plasma generator). With the help of physical and chemical etching, the rate of etching or plasma processing may be greatly improved. Generally speaking, for apparatus that possesses only RF plasma source, the plasma density and ion bombardment energy are often not simultaneously adjustable. By increasing the RF power, the plasma density and the dissociation rate of the processing gas can be increased, thereby enhancing the etching rate. However, high RF power setting may cause excessively large bombardment energy. As a result, the substrate material may be damaged due to excessive temperature or arc discharge. On the other hand, to prevent damage from excessive temperature, the range of the RF power setting may be restricted. However, the etching rate (e.g., when etching an insulating dielectric organic substrate such as epoxy resin molding compound or ABF build-up material) would be limited in a range from about 0.5 to 1 um/min as a result.

In contrast, the incorporation of a remote plasma source may boost the etching rate by 100% to 400%. For instance, compared with tools that possess only the onboard radio frequency sources, the application of remote plasma generation apparatus allows the ion bombardment energy to be adjusted (e.g., from zero ion bombardment to hundreds of volts bias). As such, the process temperature may be reduced. Take packaging process for example, the application of RPS may help to maintain the temperature of the stage to no more than 100 degrees Celsius. In some scenarios, the operating temperature is maintained under 50 degrees Celsius. In some scenarios, the operating temperature is less than 30 degrees Celsius.

With the demands for electrical compounds miniaturization, high frequency/switching speed, 5G substrate material, and micro circuit technology, there is a need for process temperature control due to the delicacy of advanced materials and the demand for high plasma uniformity over increased substrate size (e.g., panel-level process), and the challenge of advanced fabrication process inevitably increases. To this end, the higher etching performance and lower operating temperature provided by the etching equipment 100 in accordance with the instant disclosure allow it to replace traditional polishing process in many applications, thereby avoiding the problem of chip damage. Meanwhile, the use of high-density free radicals generated thereby may also increase etching rate, thereby ensuring improved productivity and yield.

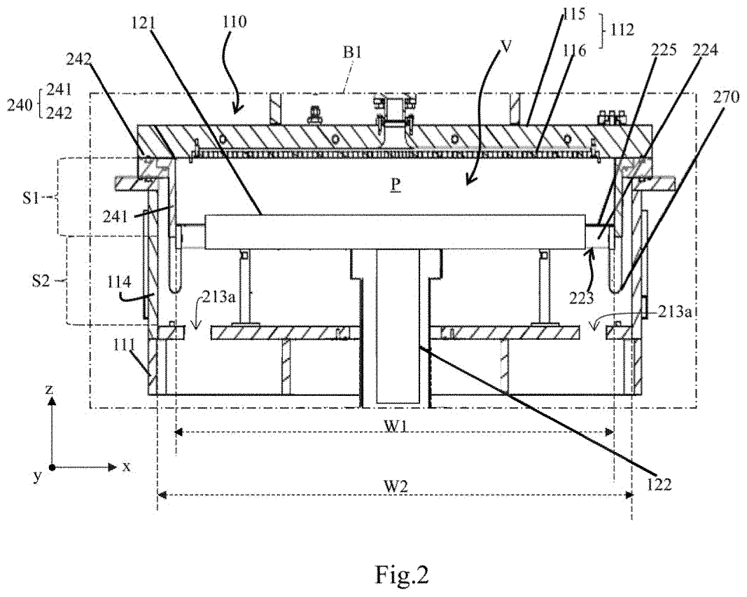

FIG. 2 shows an enlarged regional view of an etching equipment according to some embodiments of the present disclosure. For simplicity and clarity of description, some details/sub-components of the exemplary system are not marked/shown in this figure. In some embodiments, FIG. 2 may represent a partial enlarged view as indicated by the dashed box B1 as shown in FIG. 1.

In some embodiments, the baffle ring 240 of the etching equipment generally comprises two portions: a partition wall 241 and a flange 242. As shown in the figure, the flange 242 extends generally transversely (for example, along the x-y plane) and is arranged to situate between the base 111 and the plasma intake wall 112. In the illustrated embodiment, the laterally extending surface of the flange 242 provides a closing/sealing interface between the baffle ring 240 and the chamber body 110 or chamber 110. The partition wall 241 extends substantially in a longitudinal direction (for example, along the z direction), and is arranged to be seated between the lateral inner chamber wall 114 of the base 111 and the substrate support 120. In the illustrated embodiment, a gap is maintained between the downward-extending partition wall 241 and the inner chamber surface of the chamber body 110. As a whole, the inner surface of the chamber wall 114 and the inward-facing lateral surface of the retaining ring 240 respectively form the lateral surrounding wall at different height segments in the processing chamber 110 (e.g., as shown by segments S1 and S2 in the figure). The inner surface of the aforementioned surrounding wall defines an inner space V, which has two or more width segments (e.g., respectively denoted as W1 and W2). For example, in the schematic cross-sectional view of the exemplary chamber 110, the surrounding wall (which is cooperatively defined by the lateral wall 114 and the retaining ring 240) is formed with a first segment S1 and a second segment S2 with unequal widths. In the illustrated embodiment, the first segment S1, which is relatively close to the plasma intake wall 112, is provided with an inner diameter (i.e., the separation denoted as the first width W1) that is marginally larger than the overall width of the substrate support 120 to allow the entrance/passage of the substrate support 120 into the volume that corresponds to the first segment S1. In some embodiments, the upper chamber region that corresponds to the first segment S1 forms a processing region P for the substrate support 120, while the wider lower subspace corresponding to the second segment S2 forms a loading region of the inner space V.

In some embodiments, the surrounding wall around the first segment S1 is provided with a circumferentially continuous arrangement to substantially prevent easy passage/leaking of processing gas and/or plasma out of the processing region P (through the gap between the baffle ring 240 and the edge of the substrate support 120). When the substrate support 120 is moved into the process region P (e.g., in the position shown in FIG. 2), radicals from the RPS (e.g., through the diffusing plate 116) may be substantially confined in the process region P. In this way, processing gas and/or plasma may be kept from flowing into the lower subspace under the substrate support 120, thereby maintaining processing gas and/or plasma in the process region P. In the illustrated embodiment, the baffle ring 240 continuously surrounds the outer periphery of the substrate support 120 to form a narrow gap there-with, thus substantially blocking processing gas and/or plasma from passing into the lower region of the inner space V. In some embodiments, the height (e.g., in the z-direction) of the first segment S1 is not less than 200 mm. With this arrangement, the height of the process region P (i.e., the distance between the substrate support surface and the spray head 116) may reach at least 200 mm. In the illustrated embodiment, the inner diameter W1 is approximately maintained at a predetermined constant value within the range of the first segment S1. In the schematic cross-sectional view of the exemplary processing chamber 110, the length of an inner surface of the partition wall 241 of the retaining ring 240 (as a part of the inner surface of the surrounding wall) defines the first segment S1 (e.g., z direction), and is set to be greater than 200 mm (e.g., 220 mm).

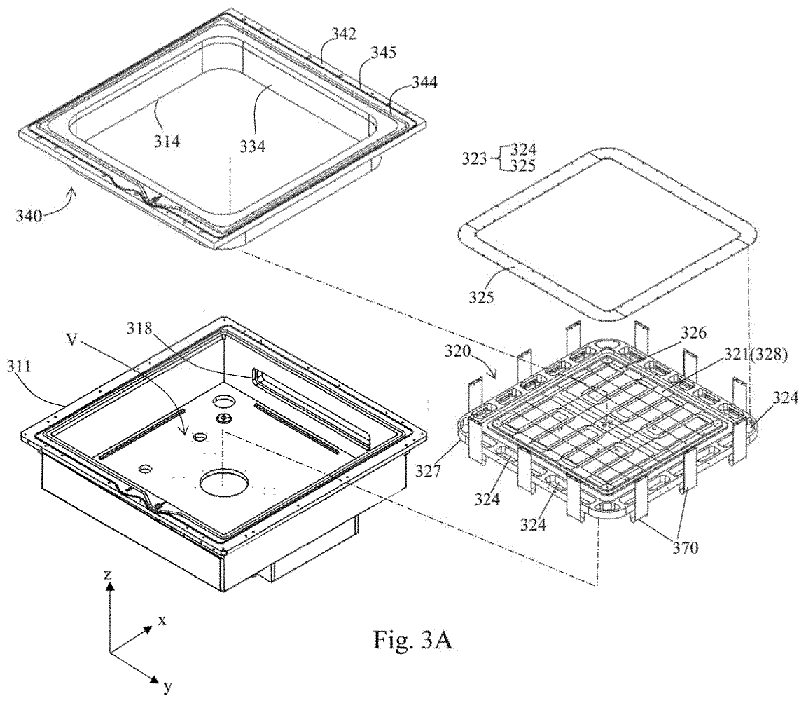

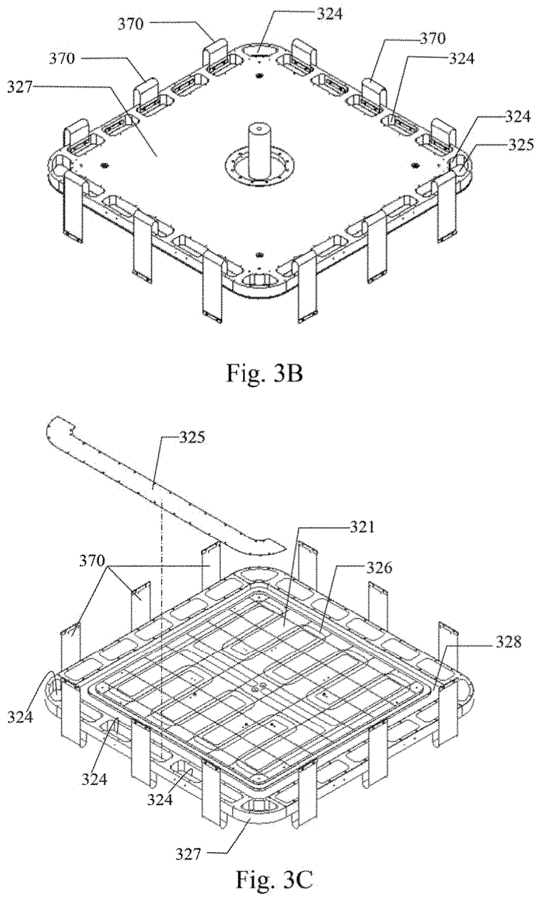

In some embodiments, the entrance and exit (e.g., port 318 of FIG. 3A) for the substrate to be moved out or into the processing chamber is provided in the lower segment of the chamber (e.g., second segment S2). When the substrate support 120 is lowered to the segment that corresponds to the second segment S2, the loading/unloading operation of a workpiece (e.g., substrates) may be performed. The inner diameter W2 of the second segment S2 is larger than the inner diameter W1 of the first segment S1. Such inner width arrangement helps to facilitate easy loading/unloading operation for the substrate support 120. In the illustrated embodiment, the difference in the inner diameters of the sidewalls in the chamber body 110 is formed by the incorporation of a separate baffle ring 240 having a different (narrower) inner diameter. In other embodiments, the inner width differential between the first and the second segments may be realized through an integral structure in the chamber side wall.

In some embodiments, the substrate support 120 is further provided with a fluid channel structure at the edge region thereof. The fluid channel structure (e.g., gas passage 223 as shown in instant figure and FIGS. 3B and 3C) includes a perforated plate 225/325 and an exhaust port 224/324 formed in the edge region of the substrate support 120 (to be arranged under the perforated plate 225/325). When an exhaust apparatus (not shown in the figure) is activated, byproducts in the processing region P may be extracted to the space below the substrate support 120 (corresponding to the second segment S2) through the gas passage 223. The ports in the perforated plate 225/325 may be substantially evenly distributed in predetermined patterns, so as to allow byproducts to evenly flow into the subspace below the processing region P (under the substrate support 120). In some embodiments, the aperture of the perforated plate is in a range from about 0.5 to 5 mm (e.g., 1 mm).

In the illustrated embodiment in FIG. 2, the processing chamber 110 further includes exhaust ports 213a. By-products can be exhausted from the chamber through the ports 213a. The exhaust ports 213a are arranged adjacent to two opposite sides of the processing chamber 110, respectively. In the illustrated embodiment, the exhaust ports 213a are arranged under the perforated plate 225 and projectively overlapped with the exhaust port 224. In some embodiments, the diameter of the pumping channel (for example, the pumping port 213a) is substantially in the range of 25 mm to 150 mm.

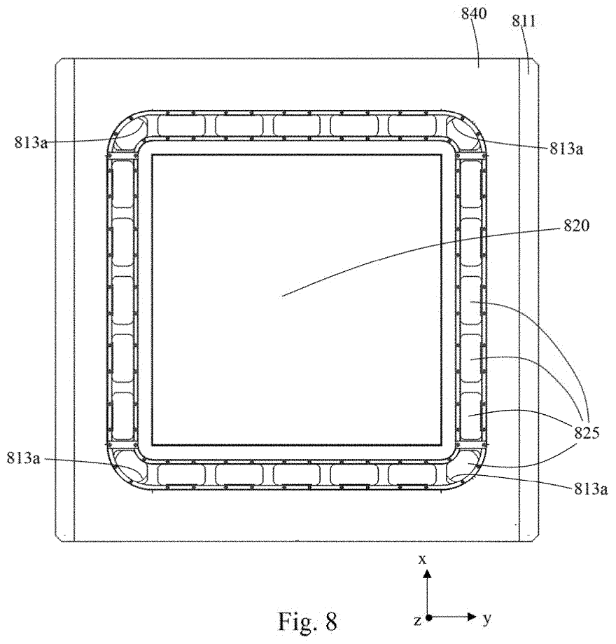

Please refer to FIG. 8, the number and location of the exhaust/pumping ports may affect/be utilized to optimize the uniformity of gas exhaustion. For example, in the embodiment shown in FIG. 8 (in which the aforementioned perforated plate is omitted for clarity of illustration), the exemplary processing chamber 811 is provided with a baffle ring 840, and a substrate support 820 is disposed within the retaining ring 840. The illustrated processing chamber 811 is provided with four pumping ports 813a, which are arranged to overlap the four exhaust ports 825 at the corners of the substrate support 820. Such a symmetrical arrangement may help to enhance uniformity of gas exhaustion.

In the placement of the carrier, if the edge of the substrate support 120 (e.g., carrier) is too close to the surrounding surface of the first segment S1 (e.g., the inward-facing surface 241 or the partition wall 241 of the baffle ring 240), during the elevator movement of the substrate support 120, the outer edge of the substrate support 120 may rub against the inner surface of the first segment S1 of the annular wall. Such friction may shorten the life of the apparatus, and may also produce particles that pollute the internal environment of the processing chamber. In some embodiments, a gap of a proper width is reserved between the inner surface of the first segment S1 (for example, the inner surface of the retaining ring 240 or the baffle ring 240) and the outer periphery of the substrate support 120. In some embodiments, a width of the gap is in a ranged from about 0.2 to 0.8 mm (e.g., 0.8 mm).

In some embodiments, a ratio between the aperture diameter of the perforated plate and the width of the stage edge gap is in the range of about 0.6 to 25. However, if the gap is substantially larger than the aperture of the perforation, undesirable leaking of processing gas/free radicals may become pronounced, which may again cause uneven distribution of the reaction gas. In addition, the impact of operating temperature on the hardware during device operation also needs to be taken in design considerations. For example, while the gap width between the hardware structures depends on the precision of modern machining (which can be kept fairly small), if the gap dimension is too small (for example, less than 0.8 mm), the gap may be compromised due to thermal expansion of the tool components caused by the elevated temperature during operation. For example, in some processes under high temperature conditions, thermal expansion of the substrate support 120 may inevitably occur. As a result, the outer edge of the substrate support 120 may extend to reach the inner surface of the first segment S₁. It has been found that a gap width design proximate the aperture size of the perforated plate helps to maintain uniform distribution of processing gas over the substrate support 120. For instance, in some embodiments, the gap width between the stage and the baffling ring is arranged to be substantially equal to the width of an aperture in the perforated plate. In some embodiments, a ratio between the aperture diameter of the perforated plate and the width of the stage edge gap is in the range of about 0.7 to 1.3, for example, 1.25. Meanwhile, the incorporation of a corresponding heat sink/dissipating mechanism on the substrate support to keep substrate temperature in check (e.g., below 140 degrees Celsius) also helps to ensure fabrication quality and maintain the normal operation of the processing apparatus.

On the other hand, the RF return path of the plasma generating device may be interrupted due to the aforementioned stage edge gap. In some embodiments, the substrate support 120 may be electrically coupled to the processing chamber 110 through one or more flexible conductive members (for example, pliable conductive member 270) to establish an RF return path. For example, in the illustrated embodiment, one end of the pliable conductive member 270 is electrically connected to the first segment S1 of the surrounding wall, and the other end is connected to the substrate support 120. In some embodiments, the substrate support 120 is electrically coupled to the baffle ring 240 through a plurality of pliable conductive members 270. In some embodiments, the placement of the pliable conductive member 270 may offset the outer periphery of the substrate support 120 and the inner surface of the retaining ring 240. In the illustrated embodiment, the partition wall 241 of the baffle ring 240 is structurally separated from the chamber side wall 114. Meanwhile, one end of the pliable conductive member 270 is fixed the partition wall 241 at a location facing the chamber side wall 114 (e.g., through a fixing member, such as a screw). The other end of the pliable conductive member 270 is fixed at the location of the exhaust port 224 situated at the periphery region of the substrate support 120. The pliable conductive member 270 is provided with a length sufficient to maintain a state of physical contact with the substrate support 120 during the elevator movement. For instance, when the substrate support 120 is in the position shown in the figure, the pliable conductive member 270 is hung between the side wall 114 and the substrate support 120 in a suspended manner.

The pliable conductive member 270 may be a strip, wire, or cable that provides an RF conductive medium. In some embodiments, the pliable conductive member 270 may be implemented as a flexible strip made of a conductive material, or a flexible strip with conductive coating. In some embodiments, the material of the flexible conductive member may be metal, such as copper. In some embodiments, the flexible conductive member may include a composite structure, for example, a heterogeneous material structure, such as silver plated over a pliant copper strip. In some embodiments, the thickness of the flexible conductive member is not greater than 1 mm (e.g., less than 0.6 mm). In some embodiments, the thickness of the flexible conductive member is about 0.2 mm. The pliable conductive member 270 can ensure continuous electrical coupling between the processing chamber and the RF power source. The return path arrangement for the RF current may be determined based on the electrical properties (e.g., conductivity/impedance) and placement of the pliable conductive member 270. In addition, the positions or separation distance between the pliable conductive members 270 may be further tuned to modify the uniformity of electrical field, thereby increasing the uniformity of gas/plasma distribution and process stability.

FIG. 3A shows an isometric exploded illustration of components for a substrate manufacturing equipment according to some embodiments of the present disclosure. For simplicity and clarity of illustration, some details/subcomponents of the exemplary system are not explicitly labeled/shown in this figure, for example, the plasma intake wall and the remote plasma source are omitted from instant view. FIGS. 3B and 3C respectively show a three-dimensional schematic diagram of a substrate support according to some embodiments of the present disclosure.

The exemplary base 311 substantially resumes the shape of a rectangular trough, which has a generally planar bottom plate and four chamber side walls that cooperatively define an internal space V for accommodating a substrate support (e.g., stage 320). In some embodiments, one of the four side walls of the base 311 is provided with a load port 318 to enable access of the substrate into/out of the internal space V. The chamber side wall is further provided with a valve configured to close the load port 318. Prior to a thinning process or plasma treatment (such as etching, cleaning, surface activation), the substrate support 320 may be moved to a corresponding position (e.g., corresponding to the second segment S2 shown in FIG. 2), and the chamber load port valve may be opened for the substrate to enter the internal space V, so as to allow secure placement of the substrate on the substrate supporting surface 321 of the substrate support 320.

In the illustrated embodiment, the exemplary substrate supporting surface 321 has a substantially rectangular planar profile. For instance, the substrate support 320 in the figure is configured to resume a rectangle profile with rounded corners. The illustrated etching equipment is configured to perform plasma treatment on large size, panel-level substrates. The substrate may include metal, dielectric insulating material, photoresist, silicon wafer, glass, and other composite materials. The illustrated apparatus may handle rectangular substrates of different sizes, such as substrates with a side length in a range from about 200 to 650 mm.

In some embodiments, the substrate support 320 includes channel arrangement configured to allow passage of the processing gas/free radicals (e.g., for gas extraction). In some embodiments, the channel arrangement (e.g., gas passage 323) is arranged along the periphery region of the substrate support 320, and has strip-shaped elements that form an encircling pattern. The gas passage 323 includes a plurality of exhaust ports 324 arranged along the edge regions of the substrate support 320, and are configured to enable fluid communication between the two opposite surfaces of the substrate supporting surface 321. The gas passage 323 further includes a perforated plate 325 disposed over the exhaust ports 324.

The perforated plate 325 is configured to cover the exhaust ports 324, and is arranged in a manner facing the plasma intake wall (e.g., the plasma intake wall 112 shown in FIG. 1). The perforated plate 325 is provided with a plurality of substantially uniformly distributed apertures. In some embodiments, a width of the aperture of the perforated plate is in a range from about 0.5 to 5 mm (e.g., 1 mm). In some embodiments, the gas passages 323 are distributed substantially symmetrically about the geometric center of the substrate support 320. In some embodiments, the exhaust ports 324 may be equidistantly distributed along two opposite sides or all four sides of the substrate support 320. The symmetrical arrangement of the gas passages 323 may contribute to the uniformity of free radical/processing gas distribution. In the illustrated embodiment, the exhaust ports 324 are not only distributed along the four sides of the substrate support 320, but also formed at the four respective corner regions of the substrate support 320. That is, the gas passages 323 are distributed along the entire periphery of the edge region of the substrate support 320 and surround the substrate supporting surface 321. Such arrangement may help to further maintain the uniformity of gas exhaustion and reduce the phenomenon of free radicals/processing gas gathering at the corner regions of the pedestal.

In the embodiment illustrated in FIG. 3A, the four sides of the substrate support 320 are provided with pliable conductive members 370, so that the potential distribution in the processing chamber may be more uniform. In some embodiments, the placement of the pliable conductive member 370 avoids the front/load port side of the substrate support 320 (i.e., the side closest to the load ports 318 in the x direction). Such arrangement enables easier loading and/or unloading operations of the substrate. In the embodiment illustrated in FIG. 3C, the rear side opposite to the front side is also kept free from the placement of flexible conductive member, in order to preserve symmetry and uniformity of the inner chamber potential distribution.

In the embodiment illustrated in FIG. 3C, the substrate support 320 is further provided with a fluid channel structure 326 having serpentine routing and embedded under the substrate supporting surface 321. The fluid channel structure 326 is configured to receive fluid (water or other cooling medium) from a coolant source to adjust the temperature condition of the substrate over the substrate supporting surface 321. For example, when performing a thinning process on the illustrated apparatus, the etching rate of the substrate may be substantially proportional to the substrate temperature. The fluid channel structure 321 or the substrate supporting surface 321 of the substrate support 320 may be used to maintain workpiece (e.g., substrate) temperature below about 140° C. In other operating scenarios, such as a photoresist ashing process, the temperature state of a substrate may be maintained in a range of, e.g., between 250 and 300° C.

In the embodiment illustrated in FIG. 3C, the substrate support 320 further includes a support plate 327, which is arranged substantially parallel to the spray head 116, and is configured for elevator movement (i.e., travel along the z axis or z-direction). The peripheral area of the support plate 327 forms the exhaust port array (ports 324). The aforementioned plurality of pliable conductive members 370 are fixed at the respective locations of the encircling array of exhaust ports 324. In some embodiments, the support plate 327 includes a conductive material, such as copper. A carrier plate 328 is disposed at the center of the supporting plate 327 to form the substrate supporting surface 321 and the fluid channel structure 326. In some embodiments, the stage is further provided with a positioning ring (or cover ring) arranged around the substrate supporting surface 321 and is located between the substrate supporting surface 321 and the exhaust ports 324. In some embodiments, the positioning ring comprises an insulating material, such as Al₂O₃, ZrO₂, Si₃N₄, AlN, machinable ceramics, Quartz, glass, or Teflon. When the lifting plate 327 moves along the z-axis, the substrate supporting surface 321, the gas passage 323, and the pliable conductive member 370 will move synchronously there-with.

The exemplary baffle ring 340 includes a generally annular structural profile that defines a substantially continuous inner surface 334 in the circumferential direction (e.g., along the inner periphery). The planar profile of the inner surface 334 substantially resumes a rectangular shape with rounded corners. In some embodiments, the baffle ring 340 includes a conductive material, such as aluminum. The top surface of the flange 342 of the baffle ring 340 is further provided with a sealing member (for example, a sealing ring 344) for maintaining air tightness of the processing chamber upon closure. The top surface of the flange 342 of the baffle ring 340 may also be provided with an electromagnetic interference (EMI) shielding element (such as a conductive gasket 345). Likewise, sealing members and EMI shielding elements may be selectively provided on the contact interface between the chamber base 311 or the base 311 and the flange 342. In the illustrated embodiment, the base 311 is electrically connected to the lid via the baffle ring 340, so that the base 311, the baffle ring 340 and the lid share equal potential. The encircling partition wall 341 shown in the figure is formed from the assembly of a plurality of components in a sealed manner. Such composite arrangement helps to ease hardware manufacture complexity, e.g., when fabricating the rounded profiles at the corners.

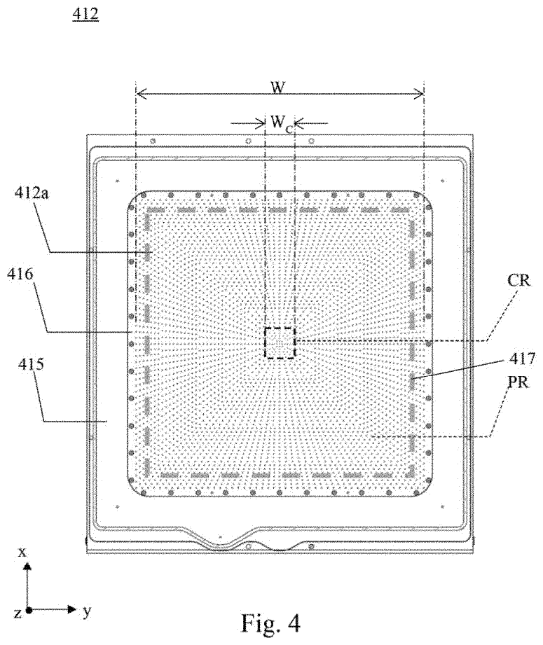

FIG. 4 shows a schematic illustration of a bottom face of a plasma intake wall according to some embodiments of the present disclosure. For simplicity and clarity of description, some details/sub-components of the exemplary system are not explicitly marked/shown in this figure. In some embodiments, FIG. 4 is a planar view along the section line IV-IV parallel to FIG. 1.

The plasma intake wall 412 shown in FIG. 4 comprises a lid 415 and a diffusing plate 416. The diffusing plate 416 has a substantially rectangular shape with rounded corners. In some embodiments, the diffusing plate 416 and the lid 415 may be made of conductive materials (such as aluminum) and be in electrical communication with each other. The plasma intake wall 412 has a hole configuration 412a configured to face toward the substrate support (for example, the substrate support 120 of FIG. 1) in the chamber. The overall layout of the hole configuration 412a presents a substantially rectangular profile. In the illustrated embodiment, the hole configuration 412a is made up with a plurality of rectangular ring-shaped hole patterns (e.g., the pattern indicated by the dotted line 417), distributed in a substantially concentric manner. The hole patterns in a concentric rectangular layout facilitate the uniform flow of processing gas/free radicals over a substantially rectangular workpiece (e.g., a panel-level substrate). In some embodiments, in each of the rectangular hole patterns, a distance or circumferential hole distance between adjacent holes (in the circumferential direction) is in a range of about 10 to 25 mm. In some embodiments, the distance is in a range of about 10.5 to 21.3 mm. The regular circumferential spacing may contribute to the uniformity of free radical distribution. In some embodiments, a diameter of the distribution hole is not greater than 2 mm (e.g., such as 1.8 mm). The dispensing angle/outlet direction of the distribution hole may be set to be parallel to the direction of the elevator movement of the substrate support (for example, in the z direction).

In some embodiments, the hole configuration 412a has a central area CR or center region CR in the hole configuration. The central region CR is configured to alleviate ultraviolet light exposure from a remote plasma source toward a process workpiece (e.g., substrate). The provision of the central region CR may also restrict free radicals from directly reaching and etching the substrate. For example, in some embodiments, a size of the holes in the central region CR is smaller than that of the holes in the surrounding peripheral region PR, so as to reduce the direct ultraviolet light exposure to the substrate. In some embodiments, the width or diameter of the hole in the central region CR may be less than about 1 mm, such as 0.8 mm. In some embodiments, the width of the hole in the peripheral area PR may be greater than about 1.5 mm, such as 1.8 mm. In some embodiments, the hole density in the central region CR is lower than the density of holes in the peripheral region. In some embodiments, the dispensing direction/outlet angle of the holes in the central region CR may be arranged offset the elevatory direction (e.g., the z direction) of the substrate support (e.g., in a tilted manner). In some embodiments, the central area CR presents a substantially rectangular layout. In some embodiments, the pattern width We may account for about 8 to 10% of the total pattern width W of the diffusing plate 416. The ratio of the central pattern area to the overall pattern coverage calls for mindful design considerations. If the central area CR is too large, it may hinder the uniform distribution of processing gas; if the ratio is too small, it may provide insufficient ultraviolet blockage for the substrate, which may result in the insufficient reduction of regional etch rate (e.g., in the region of the substrate that projectively overlaps with the central region CR). In some embodiments, a ratio between the overall pattern coverage to the central pattern size is in a range of about 60:1 to 120:1.

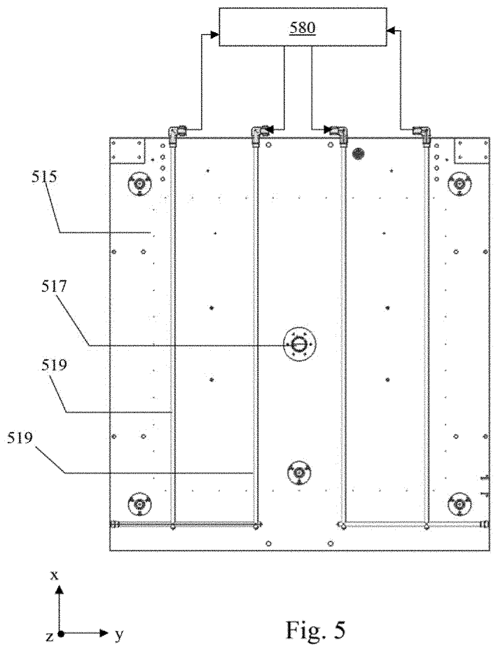

FIG. 5 shows a schematic cross-sectional view of a plasma intake wall according to some embodiments of the present disclosure. For simplicity and clarity of description, some details/sub-components of the exemplary system are not explicitly marked/shown in this figure. In some embodiments, FIG. 5 represents a cross-sectional view along the section line V-V in FIG. 1.

The cover 515 on the plasma intake wall shown in FIG. 5 is provided with an inlet port 517 configured to receive processing gas/free radicals from a remote plasma source. In some embodiments, the inlet port 517 is provided in the central region of the cover 515. In some embodiments, the central area (e.g., corresponds to the central area CR of FIG. 4) of the hole configuration (such as the hole configuration 412a shown in FIG. 4) projectively overlaps the inlet port 517, thus providing blockage against the direct ultraviolet input from a RPS. In some embodiments, the projection of the inlet port 517 (e.g., on x-y plane) falls within the aforementioned central region CR. In some embodiments, the inlet port defines a first geometric planar profile; the central region defines a second geometric planar profile, and the first geometric plane profile is substantially different from the second geometric plane profile. In some embodiments, the inlet port 517 presents a substantially circular planar profile, while the central region CR has a substantially rectangular planar profile.

In some embodiments, the cover 515 of the plasma intake wall is further provided with a flow runner/channel network (e.g., channel pattern 519) that offsets the central region thereof. The flow channel 519 is configured to establish fluidic communicate with a fluid source 580. In some operating scenarios, when the temperature state of the cover 515 is not high enough (e.g., lower than 30 degrees Celsius), process byproducts (e.g., CₓH_{y}O_{z}, CₓF_{y}) may condense on the cover 515 and/or the spray head (e.g., diffusing plate 116 as shown in FIG. 1). The generation of such condensation may hinder chamber maintenance efforts, and may also affect longevity of the hardware components. By controlling the temperature setting of the fluid source 580, the temperature state of the cover 515 and/or the shower head may be adjusted to prevent such condensation, thereby ensuring surface characteristics of the cover 515 and/or the spray head. For example, in a thinning process, proper temperature setting of the fluid source 580 (e.g., maintaining temperature state of the cover 515 at about 30 to 100 degrees Celsius) may help reducing condensation of byproducts over the internal hardware. The fluid runners shown in the figure can be formed by drilling. In other embodiments, the flow channel 519 in the cover 515 may be formed by computerized numerical control (CNC) techniques.

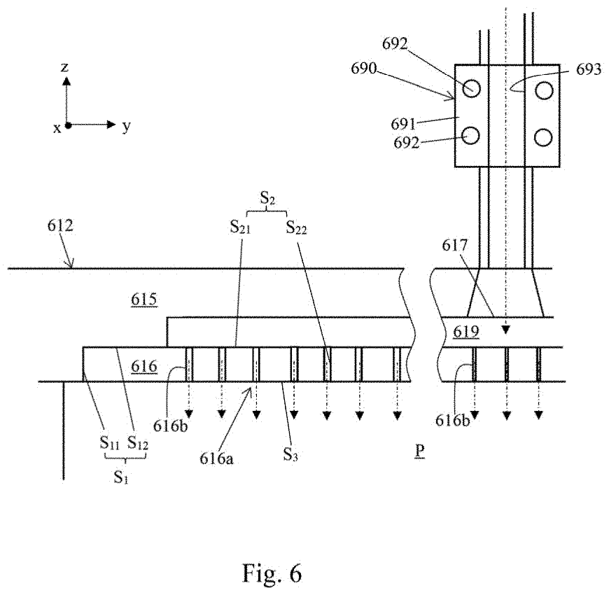

FIG. 6 shows a schematic regional cross-sectional view of a plasma intake wall according to some embodiments of the present disclosure. For simplicity and clarity of description, some details/subcomponents of the exemplary system are not explicitly marked or shown in this figure.

The plasma intake wall 612 has a hollow structure that defines a plasma distributing volume 619, which is in fluid communication with the inlet port 617 and the holes 616b. The output from the remote plasma source (not shown in the figure) may enter the plasma distributing volume 619 through the inlet port 617, and then enter the processing region P for the substrate support 120 (e.g., stage as shown in FIG. 1) through the holes 616b. In some embodiments, the structural design of the top and/or bottom aperture side wall profile S22 of the holes 616b may be further tuned to minimize flow turbulence. In some embodiments, the side wall profile of the aperture is provided with chamfer profile.

In some embodiments, the device further includes a valve module 690 or valve 690, which is arranged between the remote plasma source (upstream of the valve 690, not shown in the figure) and the inlet port 617. The valve module 690 is configured to regulate fluid communication from the RPS to the processing region P. In some operating scenarios, the substrate loading and/or unloading process may disrupt the vacuum condition established in the processing region P. If the remote plasma source is kept in full fluid connection with the processing chamber, it may be susceptible to frequent pressure fluctuations and thus suffer reduction of service life. The provision of valve 690 allow blockage of the fluid communication between processing region in the chamber and the remote plasma source, thus may help to prolong the service life of the remote plasma source. In some embodiments, the valve body 691 of the valve module 690 comprises a metal material, such as aluminum or stainless steel (for example, Steel Special Use Stainless, SUS). In some embodiments, stainless steel valve body is used for its competitive cost and material strength. However, the use of SUS valve bodies may increase recombination rate of fluorine-based radicals after dissociation. Such recombination reaction (exothermic reaction) may raise temperature of the valve body. However, because heat transfer coefficient of SUS material is not comparable to that of aluminum material, the SUS valve body may more likely be prone to be worn out due to elevated temperature conditions. In some embodiments, in order to reduce the recombination of the dissociated fluorine radicals over surface of the SUS valve body, the surface of the valve body and/or the connecting pipe exposed to the free radical environment (such as the inner surface 693) may be provided with surface coating (e.g., with a layer Teflon (PTFE)). Such arrangement may help to alleviate the recombination of dissociated fluorine free radicals and the erosion of the fluorine free radicals on the valve body. In some embodiments, the valve body and the pipe are made of aluminum alloy with surface treatment (e.g., anodizing) that helps to reduce recombination of free radicals (e.g., fluorine). In some embodiments, the aluminum valve body may be used to help reduce the recombination rate of fluorine radicals. In some embodiments, the valve module is further provided with a cooling structure. The cooling structure may include a fluid channel 692 embedded in the valve body 691. The fluid channel 692 is configured to receive coolant from a fluid source. In some embodiments, the cooling structure may be further provided with a thermoelectric cooling chip. In some embodiments, the surface of the pipeline or the valve body exposed to the free radicals (e.g., the inner surface 693) may be provided with an oxide layer (e.g., anodizing) to enhance erosion resistance against free radicals. In some embodiments, the valve body may comprise a ball-valve or gate-valve type vacuum valve member configured to regulate fluid flow rate.

In the illustrated embodiment, the plasma intake wall 612 includes a lid 615 and a diffusing plate 616 or shower head 616. The lid 615 is configured to establish sealing closure of the processing chamber. In the illustrated embodiment, a shower head (for example, the diffusing plate 616) is detachably installed on the lid 615. The diffusing plate 616 is formed with a hole configuration 616a arranged in the flow path of reaction gas or processing gas (from the RPS), and is designed to uniformly guide the RPS output toward the surface of the substrate. The diffusing plate 616 may be disposed between the inlet port 617 and the substrate support. For instance, in the illustrated embodiment, the diffusing plate 616 is arranged on one side of the inlet port 617 (facing the inside of the plasma distributing volume 619) and facing the substrate support (e.g., the substrate support 120). In the illustrated embodiment, the diffusing plate 616 has a width narrower than the process region P or process area P, so that the boundary between the diffusing plate 616 and the lid 615 (e.g., the side surface S₁₁ of the shower head) falls within the projection of the process region P. In some embodiments, the shower head 616 may be configured to be wider than the process area P, so that the boundary between the shower head 616 and the lid 615 recites outside the workpiece carrying area over the substrate support. This arrangement may reduce the impact from the micro particles generated between hardware components (e.g., fastening members that join the shower projection 616 or shower head 616 and the lid 615). In the illustrated embodiment, the plasma intake wall 612 adopts a two-piece design (i.e., having structurally separated diffusing plate 616 and the lid 615). In other embodiments, the diffusing plate and the cover may be fabricated as a unitary integral structure.

In some embodiments, the surface of the shower head (such as the diffusing plate 616) may be provided with an oxide layer to inhibit the recombination of adjacent free radicals, so as to maintain the activity of the free radicals. However, the oxide layer generally has a large surface resistance, which is not conducive to building a radio frequency loop. In some embodiments, the interface S₁ between the diffusing plate 616 and the lid 615 is formed with a surface resistance value lower than that of the surface area S2 of the diffusing plate 616 (e.g., the area that is exposed to the plasma distributing volume). This design may establish a radio frequency loop through the shower head, the cover, the surrounding wall (such as the retaining ring), the pliable conductive member, the substrate support, and the RF electrode. The illustrated interface S₁ comprises a side surface portion S₁₁ and a top surface portion S12. In some embodiments, the surface area S₂ of the diffusing plate 616 exposed to the plasma distributing volume 619 comprises: 1) area S₂₁ on the top surface of the plasma distribution part 616 or diffusing plate 616 (area not in contact with the lid 615) and 2) area S₂₂ that defines the sidewall of the distribution aperture 616b or holes 616b. In some embodiments, the surface resistance value of the surface area S₃ of the diffusing plate 616 (area facing the substrate support) is also provided with lower surface resistance than that of the surface area S₂. This arrangement is conducive to the establishment of the radio frequency loop.

In some embodiments, the shower head 616 is made of conductive material, such as metal. In some embodiments, the shower head 616 may be fabricated from aluminum plate. In some methods of manufacturing shower heads, the aluminum plate is first anodized, so an oxide layer is formed over the surface of the aluminum plate. Subsequently, selective surface treatment may be performed over the aluminum plate. For instance, the oxide layer over the entire bottom surface (such as surface area S₃), the side surfaces (such as surface area S₁₁), and the peripheral portion of the top surface (such as surface area S₁₂) of the aluminum plate may be processed, so that surface resistance value over the aforementioned regions is reduced (lower than surface area S₂₁). The process may involve oxide layer reduction/removal treatment on the bottom surface, the side surface, and the periphery of the top surface, through technique such as etching or polishing. In some embodiments, it can be observed that the bottom surface (e.g., surface area S₃) and side surfaces (e.g., surface area S₁₁) of the shower head 616 are formed with metallic luster. In some embodiments, the peripheral portion (e.g., surface area S₁₂) of the top surface of the shower head 616 is formed with metallic luster. In some embodiments, the part of the shower head 616 surrounded by the peripheral portion (for example, the surface area S₂₁) is formed with a relatively darker color, such as earth color.

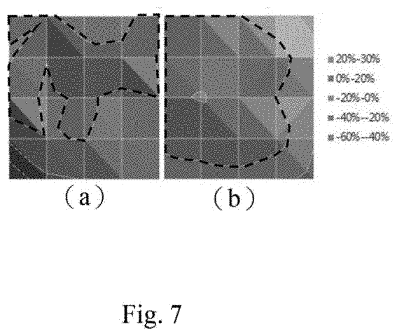

FIG. 7 shows experimental test data of an etching equipment in accordance with some embodiments of the present disclosure. The lefthand picture (a) shows the result of an etching process using a shower head without surface treatment. The righthand picture (b) shows a result of an etching process using a shower head with the aforementioned surface treatment (e.g., shower head 616 in FIG. 6). The 4×4 grid blocks shown on the left (a) and right (b) correspond to the locations of an etched surface over a rectangular substrate. Each grid block is filled with different gray scale shadings to show the etching rate measured from the experiment. The percentage range shown on the righthand side of FIG. 7 represents the percentage range obtained relative to a reference etching rate (in um/min), and is expressed in a manner corresponding to different gray scale levels. It can be observed from the data that compared to a shower head without surface treatment, the use of a shower head provided with different surface characteristics (e.g., shower head 616 in FIG. 6) may significantly improve the etch uniformity over the substrate surface. For example, the dotted lines in the pictures encircles the area with a relatively small etch rate difference/ratio (0-20%, where etch rate is more uniform). As can be seen from the figure, the dotted frame on the right picture (b) encircles a larger area. It is found that the use of the shower head in accordance with the instant disclosure (e.g., the spray head 616 in FIG. 6) may increase the uniformity of the substrate surface etch rate by more than 15% (e.g., by 16.7%).

One aspect of the present disclosure discloses an etching equipment, which includes a processing chamber and a substrate support. The processing chamber has a plasma intake wall and a surrounding wall. The plasma intake wall is configured to receive outputs from a remote plasma source. The surrounding wall has an inner surface, and the inner surface defines an inner space for receiving a substrate. The substrate support is elevatably arranged in the inner space of the processing chamber, and comprises a substrate supporting surface facing the plasma intake wall. In a cross section of the processing chamber, the surrounding wall defines a first segment and a second segment along the substrate support's direction of elevation. The first segment corresponds to a process area of the substrate support and defines a first width of separation. The second segment is farther away from the plasma intake wall than the first segment, and defines a width greater than the first width.

In some embodiments, the substrate support includes gas passage having stripe planar profile. The gas passage is formed with a plurality of exhaust ports disposed along an outer edge of the substrate support configured to enable fluid communication between opposite sides of the substrate supporting surface, and a perforated plate facing the plasma intake wall and arranged over the exhaust ports, the perforated plate having plurality of substantially evenly distributed holes.

In some embodiments, when the substrate support is in the processing region, a gap is formed between the outer edge of the substrate support and the first segment of the surrounding wall. A width of a hole of the perforated plate is substantially equal to a width of the gap.

In some embodiments, the substrate support is electrically coupled to the first segment of the surrounding wall through a plurality of (substantially even distributed) pliant conductive members.

In some embodiments, the first segment is formed with a baffle ring arranged between the processing chamber and the substrate support, the baffle ring having an inner surface that makes up a part of the inner surface of the surrounding wall.

In some embodiments, the plasma intake wall is provided with a hole configuration having a substantially rectangular planar profile arranged toward the substrate support.

In some embodiments, the plasma intake wall comprises an inlet port having a first geometric planar profile, configured to receive output from the remote plasma source. A central region of the hole configuration projectively overlaps the inlet port, and the central region has a second geometric planar profile. The first geometric planar profile is different from the second geometric planar profile.

In some embodiments, holes in the central region of the hole configuration are provided with a smaller size than holes in a periphery region that surrounds the central region.

In some embodiments, the plasma intake wall has a hollow body defining a plasma distributing volume. The hole configuration is formed on a diffusing plate arranged on one side of the inlet port that faces the substrate support. A surface area of the diffusing plate that is exposed to the plasma distributing volume has surface resistance value larger than that of a surface area of the diffusing plate facing the substrate support.

In some embodiments, the plasma intake wall comprises a lid configured to establish a sealing engagement of the processing chamber. The diffusing plate is detachably mounted on the lid. An interface between the diffusing plate and the lid is provided with surface resistance smaller than that of the surface area of the diffusing plate that is exposed to the plasma distributing volume.

Another aspect of the present disclosure discloses an etching equipment, which includes a processing chamber and a substrate support. The processing chamber defines an internal space to receive a substrate. The processing chamber includes a base, a plasma intake wall and a baffle ring. The plasma intake wall is configured to seal the processing chamber base and to receive output from a remote plasma source. The baffle ring is arranged between the base and the plasma intake wall. The substrate support is elevatably arranged in the inner space of the processing chamber and has a substrate supporting surface facing the plasma intake wall. In a cross-section of the processing chamber, the width of a processing area for the substrate support defined by the inner surface of the baffle ring is narrower than an inner separation width of the base.

In some embodiments, the substrate support includes gas passage arranged to surround the substrate supporting surface and configured to move with the substrate supporting surface concurrently. The gas passage is formed with a plurality of exhaust ports disposed along an outer edge of the substrate support that enable fluid communication between two opposite sides of the substrate supporting surface, and a perforated plate facing the plasma intake wall and arranged over the exhaust ports, the perforated plate having plurality of substantially evenly distributed holes.

In some embodiments, when the substrate support is in the processing region, a gap is formed between the outer edge of the substrate support and the baffle ring. A width of a hole of the perforated plate is substantially equal to a width of the gap.

In some embodiments, the substrate support is electrically coupled to the baffle ring through a plurality of (substantially even distributed) pliant conductive members.

In some embodiments, the plasma intake wall is provided with a hole configuration having a substantially rectangular planar profile arranged toward the substrate support.

In some embodiments, the plasma intake wall comprises an inlet port configured to receive output from the remote plasma source. Holes in a central region of the hole configuration projectively overlaps the inlet port are provided with a size smaller than holes in a periphery region that surrounds the central region.

In some embodiments, the central region has a substantially rectangular planar profile. The inlet port has a substantially circular planar profile.

In some embodiments, the plasma intake wall has a hollow body defining a plasma distributing volume. The hole configuration is formed on a diffusing plate arranged on one side of the inlet port that faces the substrate support. A surface area of the diffusing plate that is exposed to the plasma distributing volume has surface resistance value larger than that of a surface area of the diffusing plate facing the substrate support.

In some embodiments, the plasma intake wall comprises a lid configured to establish a sealing engagement of the processing chamber. The diffusing plate is detachably mounted on the lid. An interface between the diffusing plate and the lid is provided with surface resistance smaller than that of the surface area of the diffusing plate that is exposed to the plasma distributing volume.

In some embodiments, the inlet port is arranged at a central region of the lid. The lid of the plasma intake wall is further provided with fluid channels that evades the inlet port.

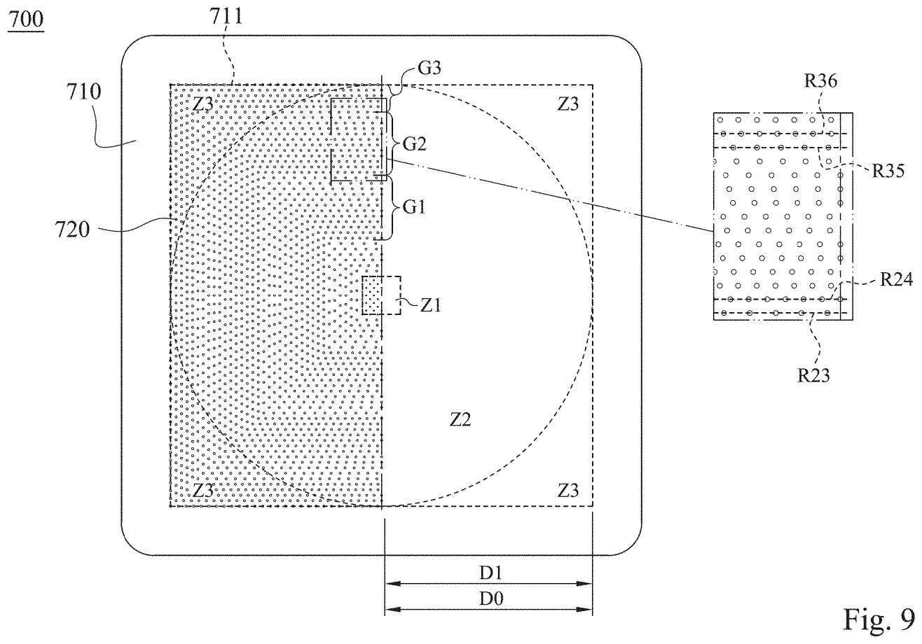

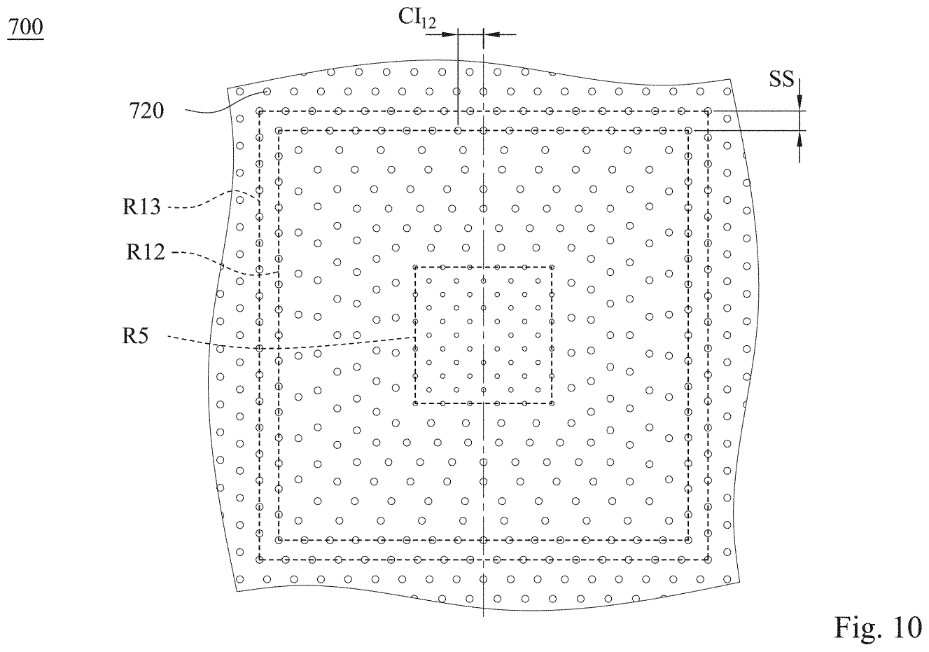

FIG. 9 shows a front view of a diffusing plate 700 according to some embodiments of the present disclosure. FIG. 10 shows a partial enlarged front view of a diffusing plate 700 according to some embodiments of the present disclosure. The diffusing plate 700 is configured for being employed in a panel-level packaging process. The material of the diffusing plate 700 may be conductive materials or non-conductive materials, preferably be aluminum alloy, and more preferably the anodic treatment may be performed on one of the surfaces of the aluminum alloy. As the material of the diffusing plate 700 is conductive, the diffusing plate 700 may be electrically floating, grounded or connected to an alternating current source, thereby achieving an effect of physical etching. The diffusing plate 700 includes a plate body 710 and a plurality of holes 720. The plate body 710 includes a rectangular hole-configuring region 711. The holes 720 are arranged in the rectangular hole-configuring region 711 and arranged concentrically to form a first to an N-th rectangular patterns from an inside to an outside sequentially, scales of the first to the N-th rectangular patterns are incrementally increased, and N is a positive integer. One portion of the holes 720 are located in an area near a center of the rectangular hole-configuring region 711, another portion of the holes 720 are located in four corner areas of the rectangular hole-configuring region 711, each of the holes has a diameter, and the diameter of the one portion of the holes 720 is smaller than the diameter of the another portion of the holes 720. In other words, sizes of the holes in a central region are smaller than sizes of the holes in the surrounding peripheral region, and the relation thereof is similar to the hole configuration 412a of FIG. 4. Details of the diffusing plate 700 will be described hereinafter.

The shape of the plate body 710 may also be rectangular as shown in FIG. 9. In other embodiments, the plate body of the diffusing plate may be circular-shaped corresponding to the applied etching equipment, and a rectangular hole-configuring region being rectangular-shaped may be defined in the circular boundary, but the present disclosure is not limited thereto. The holes 720 penetrates the plate body 710 to allow the processing gas located at an upper side of the plate body 710 to flow therethrough toward a lower side of the plate body 710. The holes 720 are configured by a rule to be arranged from the inner side to the outer side to form the first to the N-th rectangular patterns. As shown in FIGS. 9 and 10, each of four corner points of each of the first to the N-th rectangular patterns includes one of the holes 720. In other embodiments, a center point of each side of each of the rectangular patterns may include a hole, but the present disclosure is not limited thereto. In addition, in other embodiments, the center of the rectangular hole-configuring region, which may also be the center of the plate body in some embodiments, may include a hole surrounded by the first rectangular pattern. Or the center of the rectangular hole-configuring region 711 may not include any hole as shown in FIGS. 9 and 10. It is noted that, in order to clarify the drawings, one half of the holes 720 are shown, and the other half of the holes 720 are reflections on the center line. Moreover, the dotted lines of the enlarged portion of FIG. 9 respectively represent the 23-rd rectangular pattern R23, the 24-th rectangular pattern R24, the 35-th rectangular pattern R35 and the 36-th rectangular pattern R36, the dotted rectangles of FIG. 10 respectively represent the 5-th rectangular pattern R5, the 12-th rectangular pattern R12 and the 13-th rectangular pattern R13, other rectangular patterns are not labeled, and the present disclosure should not be limited by the drawings.

Each of the first to the N-th rectangular patterns may be square-shaped, ΔSᵢ may represent a side-length difference between an i-th rectangular pattern of the first to the N-th rectangular patterns and a neighboring one of the first to the N-th rectangular patterns adjacent thereto, i.e., an i−1-th rectangular pattern. Consequently, a distance SS between two neighboring rectangular patterns are equal to ΔSᵢ/2. ΔSᵢ is positive, i is an integer index representing each of the first to the N-th rectangular patterns and ranged between 1 to N, and ΔS₁ is equal to a side-length of the first rectangular pattern. Moreover, in order to cover the to-be-etched substrate in the chamber, N is so configured, with ΔSᵢ being also taken into consideration, to allow the side-length of the N-th rectangular pattern to be larger than the side-length of the substrate. For example, in one embodiment, N may be set to 32, i.e., the holes arranging from a first to a 32-nd rectangular patterns. ΔS₁ is always equal to the side-length of the first rectangular pattern whether one hole is included in the center of the rectangular hole-configuring region, ΔS₂ represents the side-length difference between the side-length of the second rectangular pattern and the side-length of the first rectangular pattern, ΔS₃ represents the side-length difference between the side-length of the third rectangular pattern and the side-length of the second rectangular pattern, and so on. Furthermore, the first to the N-th rectangular patterns may also be so configured that the side-length difference corresponding to the first to an M-th rectangular patterns is different from the side-length difference corresponding to an M+1-th to the N-th rectangular patterns, M is a positive integer, and M is smaller than N/2. Hence, in one embodiment, M may be set to 5, and ΔS₁ to ΔS₅ of the first to the 5-th rectangular patterns are different from ΔS₆ to ΔS₃₂ of the 6-th to the 32-nd rectangular patterns. For example, ΔS₁ to ΔS₅ may be set to 14 mm, and ΔS₆ to ΔS₃₂ may be set to 20 mm. Additionally, ΔSᵢ satisfies a condition of 3 mm≤ΔSᵢ≤50 mm. It is noted that the side-length in the present disclosure is defined as the length of one side of each rectangular pattern, and a perimeter of each rectangular pattern is equal to 4 times of the side-length.

The holes 720 may be so configured to have different circumferential hole distances; therefore, CIᵢ may represent a circumferential hole distance between one of the holes 720 that is located at the i-th rectangular pattern and a neighboring one of the holes 720 adjacent thereto along a side-length direction of the i-th rectangular pattern, and a condition of 0.3×ΔSᵢ≤CIᵢ≤5×ΔSᵢ is satisfied. For example, the circumferential hole distance between the neighboring holes 720 of the 12-th rectangular pattern is CI₁₂, and if ΔS₁₂ is equal to 20 mm, CI₁₂ may be ranged between 6 mm to 100 mm.

The first to the N-th rectangular patterns may be further partitioned into a plurality of groups each indexed by an integer j ranged from 1 to J. A number of the neighboring rectangular patterns starting from an i_{min,j}-th to an i_{max,j}-th rectangular patterns contained by each of the groups is equal to an interger dⱼ, wherein i_{max,j}=i_{min,j}+dⱼ−1. The circumferential hole distances CIᵢ of the rectangular patterns of each of the groups are increased as the corresponding integer index i increases. The i_{min,j}-th to the i_{max,j}-th rectangular patterns belong to one of the groups, an i_{max,j}+1-th rectangular pattern belongs to another one of the groups adjacent thereto, the circumferential hole distance of the i_{max,j}+1-th rectangular pattern is smaller than the circumferential hole distance of the i_{max,j}-th rectangular pattern, a condition of 4≤dⱼ≤N is satisfied, and J and dᵢ are positive integers. In other words, a j-th group includes the i_{min,j}-th rectangular pattern, representing the rectangular pattern having the smallest integer index i and the smallest size thereof, to the i_{max,j}-th rectangular pattern, representing the rectangular pattern having the largest integer index i and the larger size thereof, the size of the i_{max,j}+1-th rectangular pattern is larger than that of the i_{max,j}-th rectangular pattern, and the i_{max,j}+1-th rectangular pattern is adjacent to the i_{max,j}-th rectangular pattern. In one embodiment, dᵢ may be ranged from 5 to 12.

To be more specific, as shown in FIG. 9, groups G1, G2, G3 are illustrated as an example. The group G1 includes 12 rectangular patterns from the 12-th rectangular pattern to the 23-rd rectangular pattern R23, the group G2 includes 12 rectangular patterns from the 24-th rectangular pattern R24 to the 35-th rectangular pattern R35, and the group G3 includes 5 rectangular patterns from the 36-th rectangular pattern R36 to the 40-th rectangular pattern. The group G1 is more adjacent to the center of the rectangular hole-configuring region 711, and the group G2 is located between the group G1 and the group G3. As shown in FIG. 9, the circumferential hole distance of the 24-th rectangular pattern G24 is smaller than that of the 23-rd rectangular pattern G23, and the circumferential hole distance of the 36-th rectangular pattern G36 is smaller than that of the 35-th rectangular pattern G35.

Moreover, the holes 720 may be so configured that the circumferential hole distance of a largest one of the rectangular patterns of one of the groups that is away from the first rectangular pattern is smaller than the circumferential hole distance of a largest one of the rectangular patterns of another one of the groups that is near the first rectangular pattern. For example, the 23-rd rectangular pattern R23 is the largest one of the group G1, the 35-th rectangular pattern R35 is the largest one of the group G2, and the circumferential hole distance of the 35-th rectangular pattern R35 is smaller than that of the 23-rd rectangular pattern R23. Therefore, the overall densities of holes 720 of the rectangular patterns are increased further away from the center of the rectangular hole-configuring region 711, making the gas diffusing process through the holes 720 more uniform.

In the embodiment shown in FIGS. 9 and 10, the diameters of the holes 720 may be configured to be different according to different zones. As shown in FIG. 9, the rectangular hole-configuring region 711 may include a center zone Z1, an outer zone Z3 and a first concentric circular zone Z2 between the center zone Z1 and the outer zone Z3. The center zone Z1 covers the first to an M-th rectangular patterns, M is a positive integer, M is smaller than N/2, and the area near the center of the rectangular hole-configuring region 711 is located in the center zone Z1. The outer zone Z3 covers the four corner areas of the rectangular hole-configuring region 711. ϕ1 represents the diameter of any one of the holes 720 of the center zone Z1, ϕ2 represents the diameter of any one of the holes 720 of the first concentric circular zone Z2, and a condition of ϕ1≤ϕ2 is satisfied. Moreover, ϕ3 represents the diameter of any one of the holes 720 of the outer zone Z3, and a condition of 0.4 mm≤ϕ1<ϕ2<ϕ3≤2.5 mm is satisfied. In one embodiment, the shaped boundary of the center zone is circular, and covers the holes of the portions other than the M-th rectangular pattern.

It is noted that no actual boundary is located between the center zone Z1, the first concentric circular zone Z2, and the outer zone Z3, and the virtual zones are only for the clear description and the hole configuration. The center zone Z1 may include the center of the rectangular hole-configuring region 711 and the area nearby, e.g., the first to the 5-th rectangular patterns. The first concentric circular zone Z2 may have a first concentric circular boundary, D1 represents a first distance between the center of the rectangular hole-configuring region 711 and the first concentric circular boundary, DO represents a distance between the N-th rectangular pattern and the center of the rectangular hole-configuring region 711, and a condition of D1≤D0 is satisfied. Moreover, a condition of 0.7×D0≤D1≤D0 is satisfied. As satisfied the condition, the area of the outer zone Z3 is not greater than 62% of the area of the rectangular hole-configuring region 711 (62%≈1−[(0.7×D0)²π/(2×D0)²]), and the area of the outer zone Z3 is not smaller than 21% of the area of the rectangular hole-configuring region 711 (21%≈1−[(D0)²π/(2×D0)²]) Furthermore, a condition 0.9×D0≤D1≤D0 is satisfied. In the embodiment shown in FIGS. 9 and 10, the shape of the center zone Z1 is rectangular, and D1=D0. Consequently, the outer zone Z3 includes four disconnected sub-areas in the outer of the first concentric circular zone Z2, and the four corner areas are respectively located in the four disconnected sub-areas. With the configuring of different diameters in different zones, the uniformity of the processing gas as diffusing may be increased. In one embodiment, one portion of the holes are located in the outer zone, and the diameter of the aforementioned one portion of the holes is larger than the diameter of a rest portion of the holes. Moreover, a condition of 0.8 mm≤ϕ1<ϕ2<ϕ3≤2.2 mm may be further satisfied. In another embodiment, ϕ1, ϕ2 and ϕ3 may be 1.2 mm, 1.8 mm and 2.0 mm, respectively.

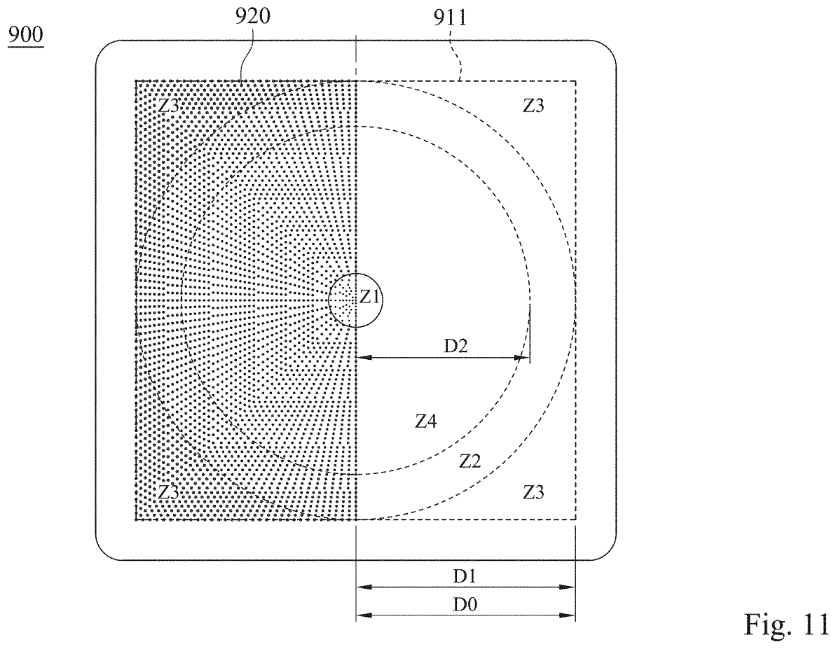

FIG. 11 shows a front view of a diffusing plate 900 according to some embodiments of the present disclosure. The diffusing plate 900 is similar to the diffusing plate 700, but a number of the rectangular patterns and details of the configuration are different. For example, one of the holes 920 are located at the center of the rectangular hole-configuring region 911, which is also the center of the plate body, a center point of each side of each rectangular pattern may include one of the holes 920, and a number of the rectangular patterns belongs to each group is different.

The rectangular hole-configuring region 911 may further include a second concentric circular zone Z4 between the center zone Z1 and the first concentric circular zone Z2. The second concentric circular zone Z4 has a second concentric circular boundary, D2 represents a second distance between the center of the rectangular hole-configuring region 911 and the second concentric circular boundary, and ϕ2′ represents the diameter of any one of the holes 920 of the second concentric circular zone Z2. Conditions of 0.3×D0≤D2≤0.8×D0 and ϕ1<ϕ2′≤ϕ2<ϕ3 are satisfied. As shown in FIG. 11, the center zone Z1 of the diffusing plate 800 may be circular-shaped and covers the first to the M-th rectangular patterns and other portions other than the M-th rectangular pattern. The first concentric circular zone Z2 and the second concentric circular zone Z4 are concentric and surround the center zone Z1. The outer zone Z3 includes four disconnected sub-areas in the outer of the first concentric circular boundary.

The diffusing plate 900 may be used in an etching equipment. The etching equipment may include a gas inlet, and the diffusing plate 900 may be disposed under the gas inlet. In one embodiment, the processing gas may be decomposed by a plasma source (such as the remote plasma source 130 shown in FIG. 1) so as to generate free radicals. In another embodiment, a number of the gas inlets may be two, and the two gas inlets may be communicated with the chamber, respectively. A substrate carrier may be disposed in the chamber and is located under the diffusing plate 900. The substrate carrier includes a rectangular effective processing region for containing at least one substrate. A side-length of the N-th rectangular pattern of the diffusing plate 900 is larger than a side-length of the rectangular effective processing region, and a ratio of the side-lengths thereof is ranged between 1.0 to 2.0. Specially, in one embodiment, the side-length of the N-th rectangular pattern of the diffusing plate may be equal to 610 mm, a side-length of the rectangular effective processing region may be equal to 455 mm, and a ratio of the side-lengths thereof may be equal to 1.34.

In one embodiment, one substrate may be disposed on the substrate carrier, and the side-length of the rectangular effective processing region may be equal to the side-length of the substrate. As a rectangular diffusing plate having a side-length of 630 mm is coordinated with a substrate having a side-length of 455 mm, the rectangular hole-configuring region may consist of the center zone and the outer zone. As a rectangular diffusing plate having a side-length of 770 mm is coordinated with a substrate having a side-length of 640 mm, the rectangular hole-configuring region may consist of the center zone, the first concentric circular zone and the outer zone sequentially. As a rectangular diffusing plate having a side-length of 970 mm is coordinated with a substrate having a side-length of 700 mm, the rectangular hole-configuring region may consist of the center zone, the second concentric circular zone, the first concentric circular zone and the outer zone sequentially. In other embodiments, a plurality of substrates may be disposed on the substrate carrier, and the side-length of the rectangular effective processing region may be equal to a sum of the side-lengths of the substrates.

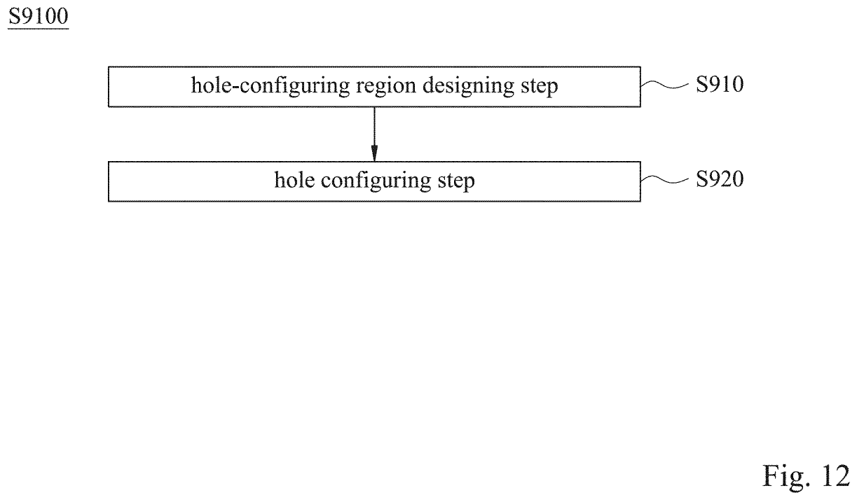

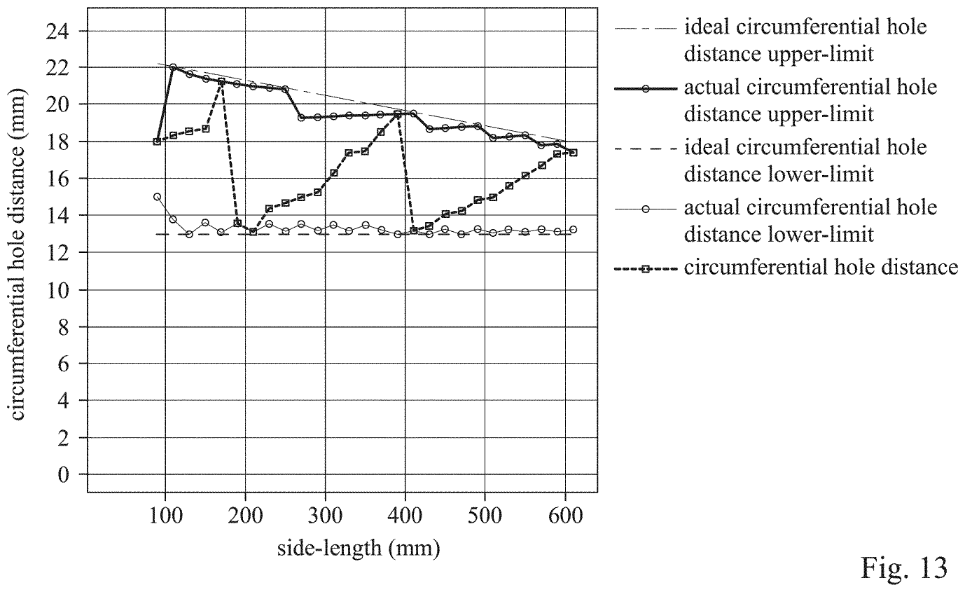

FIG. 12 shows a block flow chart of a hole configuring method S9100 for a diffusing plate according to some embodiments of the present disclosure. FIG. 13 shows a chart of circumferential hole distances and side-lengths of a hole configuring method S9100 for a diffusing plate according to some embodiments of the present disclosure. The hole configuring method S9100 includes a hole-configuring region designing step S910 and a hole configuring step S920.

In the hole-configuring region designing step S910, a rectangular hole-configuring region of a plate body of the diffusing plate is defined.

In the hole configuring step S920, positions of a plurality of holes are arranged in the rectangular hole-configuring region. The holes are arranged concentrically to form a first to an N-th rectangular patterns from an inside to an outside sequentially, scales of the first to the N-th rectangular patterns are incrementally increased, and N is a positive integer. One portion of the holes are located in an area near a center of the rectangular hole-configuring region, and another portion of the holes are located in four corner areas of the rectangular hole-configuring region. Each of the holes has a diameter, the diameter of the one portion of the holes is smaller than the diameter of the aforementioned another portion of the holes. ΔSᵢ represents a side-length difference between an i-th rectangular pattern of the first to the N-th rectangular patterns and a neighboring one of the first to the N-th rectangular patterns adjacent thereto, and ΔSᵢ is positive. CIᵢ represents a circumferential hole distance between one of the holes that is located in the i-th rectangular pattern and a neighboring one of the holes adjacent thereto along a side-length direction of the i-th rectangular pattern, i is an integer index representing each of the first to the N-th rectangular patterns and ranged between 1 to N, and ΔS₁ is equal to a side-length of the first rectangular pattern. In one embodiment, the diameter of any one of the one portion of the holes is smaller than the diameter of any one of the aforementioned another portion of the holes.

The hole configuring step S920 may include defining an actual circumferential hole distance upper-limit range (the range covering the actual circumferential hole distance upper-limit shown in FIG. 13 being defined as the actual circumferential hole distance upper-limit range) and an actual circumferential hole distance lower-limit range (the range covering the actual circumferential hole distance lower-limit shown in FIG. 13 being defined as the actual circumferential hole distance lower-limit range), partitioning the first to the N-th rectangular patterns into a plurality of groups each indexed by an integer j ranged from 1 to J, a number of the neighboring rectangular patterns starting from an i_{min,j}-th to an i_{max,j}-th rectangular patterns contained by each of the groups is equal to an interger dⱼ, wherein i_{max,j}=i_{min,j}+dⱼ−1, and configuring the circumferential hole distance CIᵢ of the i_{min,j}-th rectangular patterns of each of the groups to fall within the actual circumferential hole distance lower-limit range, configuring the circumferential hole distance CIᵢ of the i_{max,j}-th rectangular pattern of each of the groups to fall within the actual circumferential hole distance upper-limit range, configuring the circumferential hole distances CIᵢ of the i_{min,j}-th to the i_{max,j}-th rectangular patterns of each of the groups to be monotonously increasing as the corresponding integer index i increases. An i_{max,j}+1-th rectangular pattern belongs to another one of the groups adjacent thereto, and the circumferential hole distance of the i_{max,j}+1-th rectangular pattern is smaller than the circumferential hole distance of the i_{max,j}-th rectangular pattern. It is noted that, the arrangement of the holes in the arear near the center of the rectangular hole-configuring region, corresponding to the gas inlet, may be previously defined, and a side-length of the arear may be equal to 90 mm.

In the hole configuring step S920, the actual circumferential hole distance upper-limit range may be ranged between 18 mm to 22 mm, and the actual circumferential hole distance lower-limit range may be ranged between 12 mm to 14 mm. Before defining the actual circumferential hole distance upper-limit range and the actual circumferential hole distance lower-limit range, ΔSᵢ may be defined first. After defining ΔSᵢ, an ideal circumferential hole distance upper-limit range (the range covering the ideal circumferential hole distance upper-limit shown in FIG. 13 being defined as the ideal circumferential hole distance upper-limit range) and an ideal circumferential hole distance lower-limit range (the range covering the ideal circumferential hole distance lower-limit shown in FIG. 13 being defined as the ideal circumferential hole distance lower-limit range) may be defined. For example, as ΔSᵢ=20 mm, the maximum value of the ideal circumferential hole distance upper-limit range may be calculated by 1.1×ΔSᵢ and be equal to 22 mm, the minimum value of the ideal circumferential hole distance upper-limit range may be calculated by 0.9×=ΔSᵢ and be equal to 18 mm. The ideal circumferential hole distance lower-limit range may be a constant calculated by 0.65×ΔSᵢ and be equal to 13 mm. In addition, in order to ensure a number of the holes of each rectangular pattern to be an integer, one hole being located at each corner of each rectangular pattern, one hole being located at a center position of each side of each rectangular pattern, etc., the ideal circumferential hole distance upper-limit range and the ideal circumferential hole distance lower-limit range are respectively adjusted to the actual circumferential hole distance upper-limit range and the actual circumferential hole distance lower-limit range.

As shown in FIG. 13, the maximum value of the actual circumferential hole distance upper-limit range may correspond to the rectangular pattern having a side-length equal to 90 mm, the minimum value of the actual circumferential hole distance upper-limit range may correspond to the rectangular pattern having a side-length equal to 630 mm, and the values of the actual circumferential hole distance upper-limit range are distributed as a slope. Hence, the circumferential hole distance of a largest one of the rectangular patterns of one of the groups that is away from the first rectangular pattern is smaller than the circumferential hole distance of a largest one of the rectangular patterns of another one of the groups that is near the first rectangular pattern. In such configuration, the circumferential hole distance of each rectangular pattern of each group may be increased as the size/the integer index i thereof is increased. Moreover, the maximum circumferential hole distance of each groups may be decreased as the groups is far away from the center of the rectangular hole-configuring region, thereby increasing the hole density away from the center of the rectangular hole-configuring region to improve the whole diffusing uniformity.

Furthermore, in the hole configuring step S920, for each of the groups with the index j,

$${Cl}_{i} = ( \frac{( i - {i}_{min , j} ) Mod {d}_{j}}{( {d}_{j} - 1 )} ) \times a Max {Cl}_{i} + ( 1 - \frac{( i - {i}_{min , j} ) Mod {d}_{j}}{( {d}_{j} - 1 )} ) \times a Min {Cl}_{i}$$

is used to calculate the circumferential hole distance of the i-th rectangular pattern, wherein aMaxCIᵢ represents a value in the actual circumferential hole distance upper-limit range corresponding to the i-th rectangular pattern, aMinCIᵢ represents a value in the actual circumferential hole distance lower-limit range corresponding to the i-th rectangular pattern, and a condition of 4≤dⱼ≤N may be satisfied. In other embodiments, the circumferential hole distance may be adjusted manually, and it is not limited thereto.

To sum up, in the hole configuring method S9100, ΔSᵢ of each rectangular pattern may be defined first by a programmed software of a computer or a processor, or be defined manually, the ideal circumferential hole distance upper-limit range and the ideal circumferential hole distance lower-limit range are also defined by the software, and then the ideal circumferential hole distance upper-limit range and the ideal circumferential hole distance lower-limit range are respectively adjusted to the actual circumferential hole distance upper-limit range and the actual circumferential hole distance lower-limit range according to the demands that a number of the holes of each rectangular pattern is required to be an integer, one hole is required to be located at each corner of each rectangular pattern, etc., by the software. After which, using the software to partition the first to the N-th rectangular patterns into a plurality of groups each indexed by an integer j ranged from 1 to J, a number of the neighboring rectangular patterns starting from an i_{min,j}-th to an i_{max,j}-th rectangular patterns contained by each of the groups is equal to an interger d₁, wherein i_{max,j}=i_{min,j}+dⱼ−1, to configure the circumferential hole distance CIᵢ of the i_{min,j}-th rectangular patterns of each of the groups to fall within the actual circumferential hole distance lower-limit range, to configure the circumferential hole distance CIᵢ of the i_{max,j}-th rectangular pattern of each of the groups to fall within the actual circumferential hole distance upper-limit range, and to configure the circumferential hole distances CIᵢ of the i_{min,j}-th to the i_{max,j}-th rectangular patterns of each of the groups to be monotonously increasing as the corresponding integer index i increases, that is, the circumferential hole distances of the rectangular patterns of the same group are increased as the sizes of the rectangular patterns thereof are increased.

$${Cl}_{i} = ( \frac{( i - {i}_{min , j} ) Mod {d}_{j}}{( {d}_{j} - 1 )} ) \times a Max {Cl}_{i} + ( 1 - \frac{( i - {i}_{min , j} ) Mod {d}_{j}}{( {d}_{j} - 1 )} ) \times a Min {Cl}_{i}$$

may be used to obtain the circumferential hole distance. Finally, the diameters of the holes of the center zone, the first concentric circular zone, the outer zone, etc., may be adjusted according to the demands by the software. Therefore, the diffusing plate 700 shown in FIGS. 9, 10 and the diffusing plate 900 shown in FIG. 11 may be manufactured.

### Example

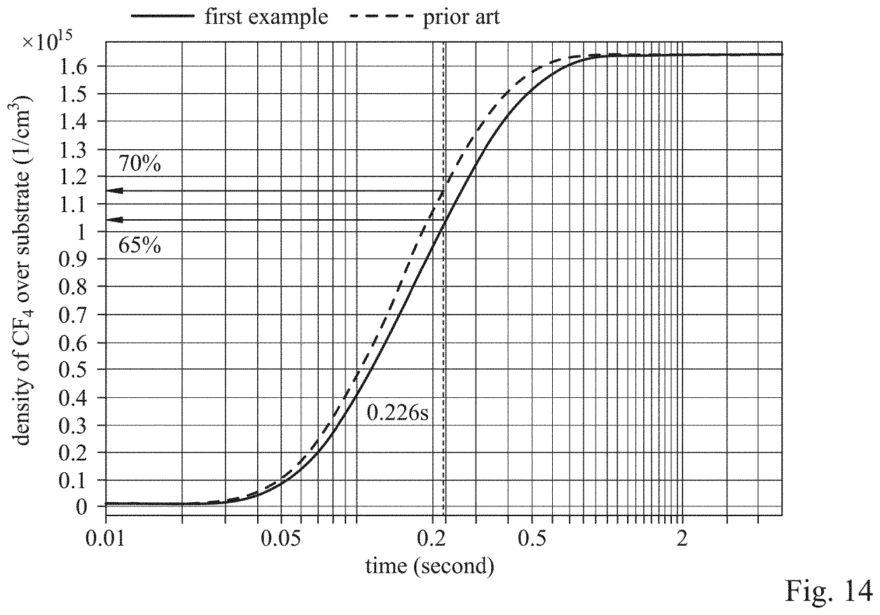

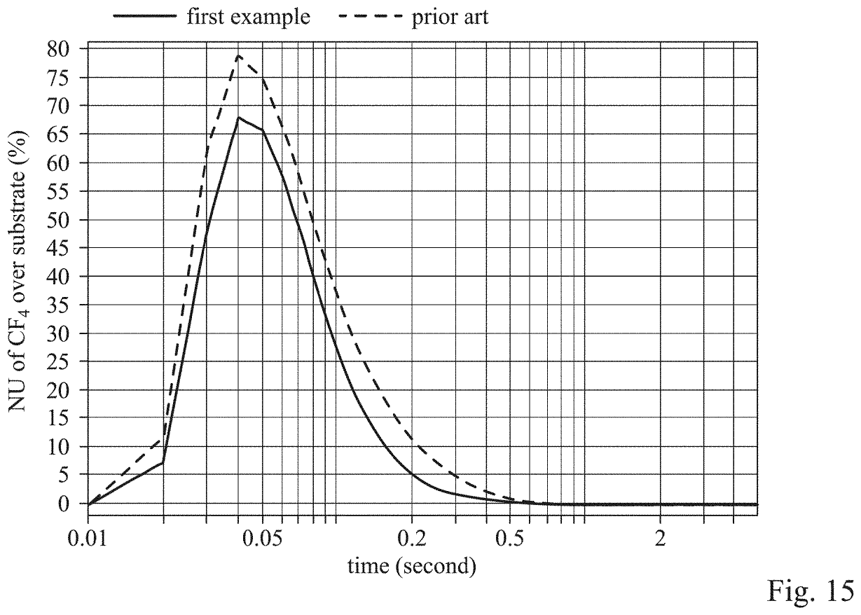

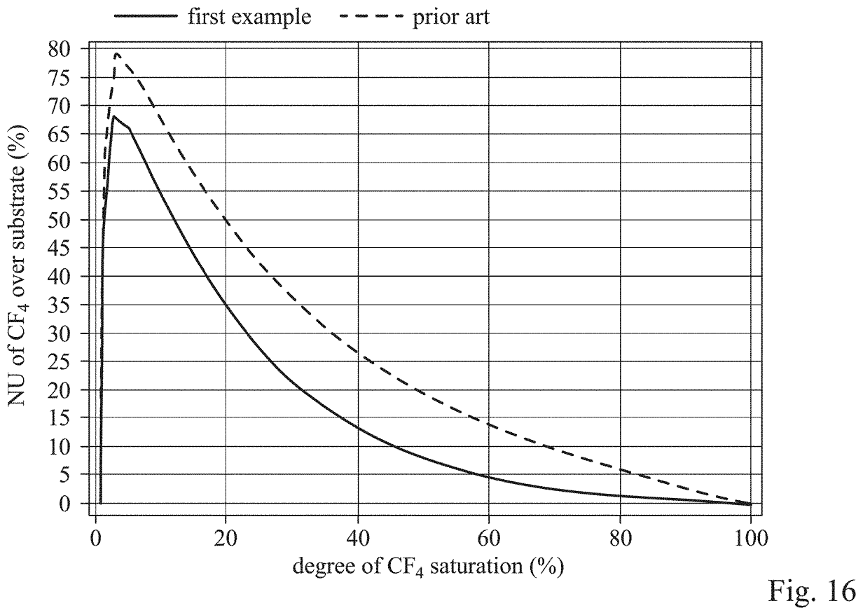

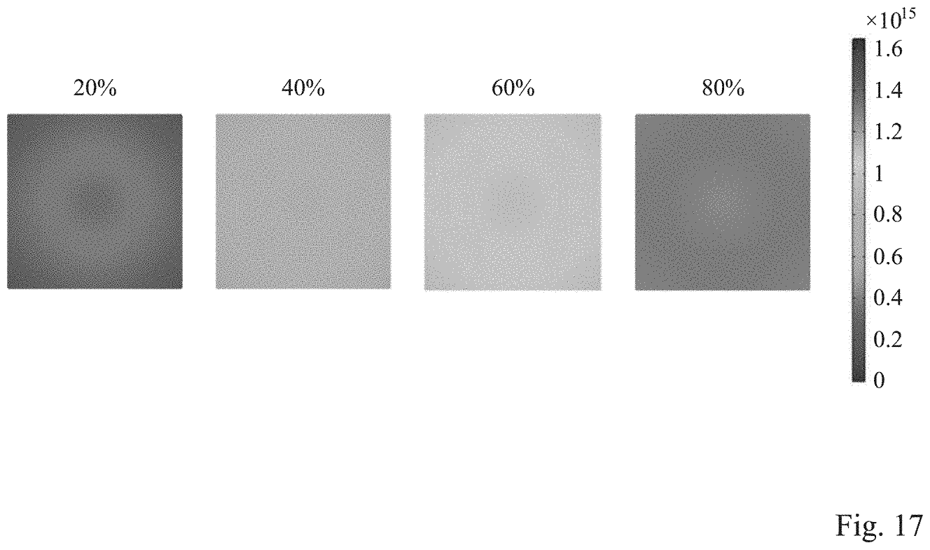

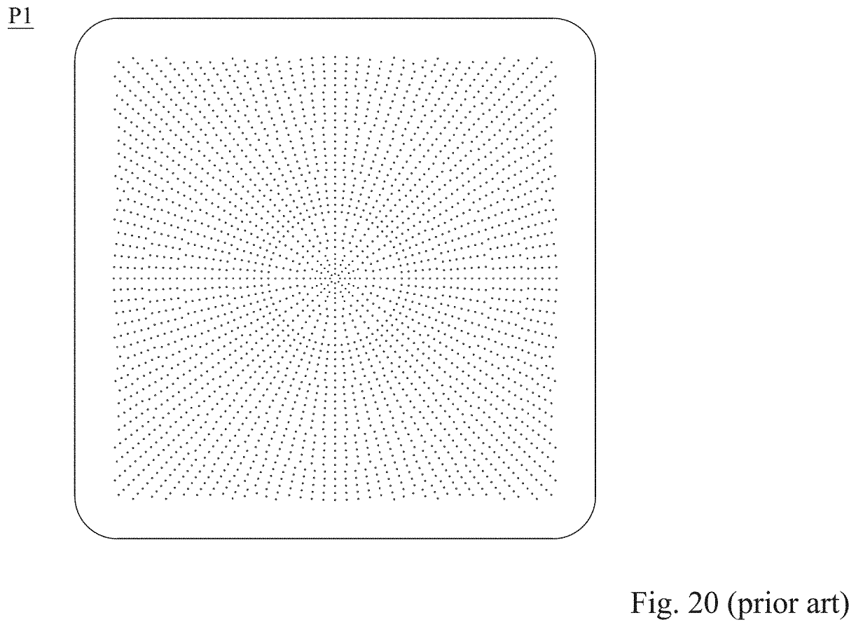

FIG. 14 shows a relation between the density and time as a diffusing plate of a first example of the present disclosure and a diffusing plate P1 of a prior art diffusing CF₄. FIG. 15 shows a relation between a CF₄ non-uniformity and the time as the diffusing plate of the first example of the present disclosure and the diffusing plate P1 of the prior art diffusing CF₄. FIG. 16 shows a relation between a CF₄ non-uniformity and the degree of CF₄ saturation as the diffusing plate of the first example of the present disclosure and the diffusing plate P1 of the prior art diffusing CF₄. FIG. 17 shows a CF₄ diffusing status and the degree of CF₄ saturation as the diffusing plate of the first example diffusing CF₄. In the first example, the holes are arranged in concentric rectangular patterns, and ϕ1, ϕ2 and ϕ3 may be 1.3 mm, 2.2 mm and 2.2 mm, respectively. The diffusing plate P1 of the prior art are shown in FIG. 20, the holes thereof are arranged in concentric circular patterns, and a number of the holes thereof is equal to that of the diffusing plate of the first example, being about 2720±30. During simulation, a pressure of the chamber may be 450 mTorr and filled of Oxygen, and CF₄ may be provided with a flow rate being 5500 sccm (Standard Cubic Centimeter per Minute). As the time is 0 second, 10% CF₄ is released.

After CF₄ enters the chamber, CF₄ may be diffused by the diffusing plate of the first example and the diffusing plate P1 of the prior art toward the vacuumed reaction area between the diffusing plate and the substrate, and may transport through convection and diffusion. The density of CF₄ over the substrate increases with time in the process until the value reaches a dynamic equilibrium where new CF₄ entering the chamber are equal to the pumped out CF₄. Since the pressure (represented by P), the volume (represented by V), and flow rates (represented by Q) of the chamber are the same for both the diffusing plate of the first example and the diffusing plate P1 of the prior art, the residence time, which is an order-of-magnitude estimate for PV/Q, is calculated to be 0.226 s. Hence, as shown in FIG. 14, the time where CF₄ density over the substrate reaches 65-70% of the saturated value is 0.226 s as diffusing CF₄ by the diffusing plate of the first example and the diffusing plate P1 of the prior art, it validates that the transportation feature of the simulation is close to the actual transportation.

The time scales of FIGS. 14 and 15 are the same. As shown in FIG. 15, large non-uniformity (NU) occurs at the time around 0.02 s to 0.04 s as first arrival of CF₄ from the gas inlet to the substrate surface. This is shown by the onset of CF₄ density increase at 0.02 s. As shown in both FIGS. 14 and 15, the density of CF₄ increases monotonously until CF₄ density reaches a saturation value indicating dynamic equilibrium, and the non-uniformity decreases monotonously after passing the maximum non-uniformity. Owing to the characteristic monotonous increase in CF₄ density over the substrate during the gas transport process, different degree of CF₄ saturation may be deemed as different time point of transportation, and the non-uniformity of the different time point may be used to judge the quality of the CF₄ transportation. As shown in the result of FIG. 16, the non-uniformity of the diffusing plate of the first example as diffusing CF₄ is smaller that of the diffusing plate P1 of the prior art, which proves that the diffusing plate of the first example has a better CF₄ (processing gas) transportation effect. Moreover, because of the uniformly transported CF₄, the non-uniformity of etching can be reduced. Furthermore, as shown in FIG. 17, as using the diffusing plate of the first example to diffuse CF₄, the uniformity of the corners of the substrate are better. As a result, as the holes of the diffusing plate are arranged in concentric rectangular patterns, the transportation uniformity of CF₄ is better than that of the diffusing plate P1 of the prior art where the holes are arranged in concentric circular patterns.

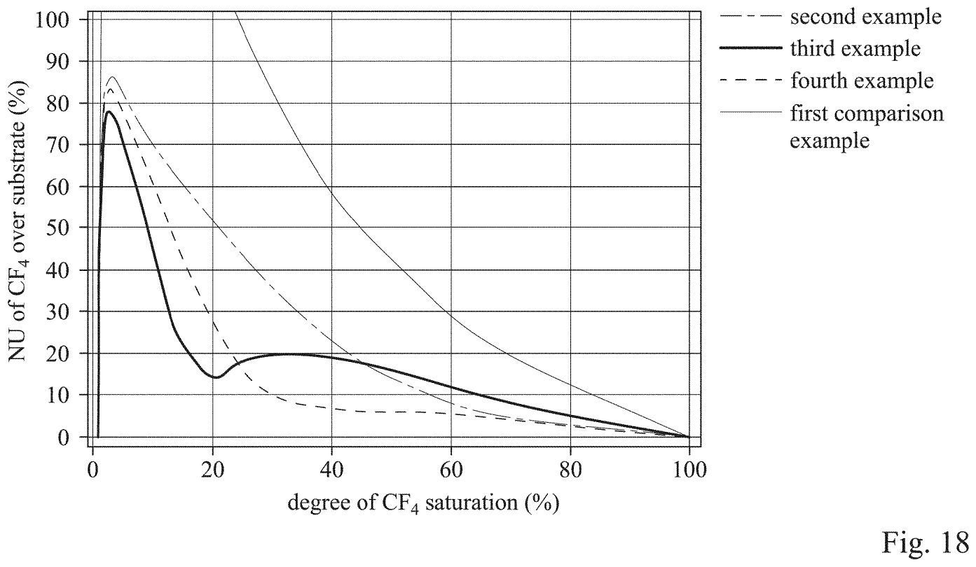

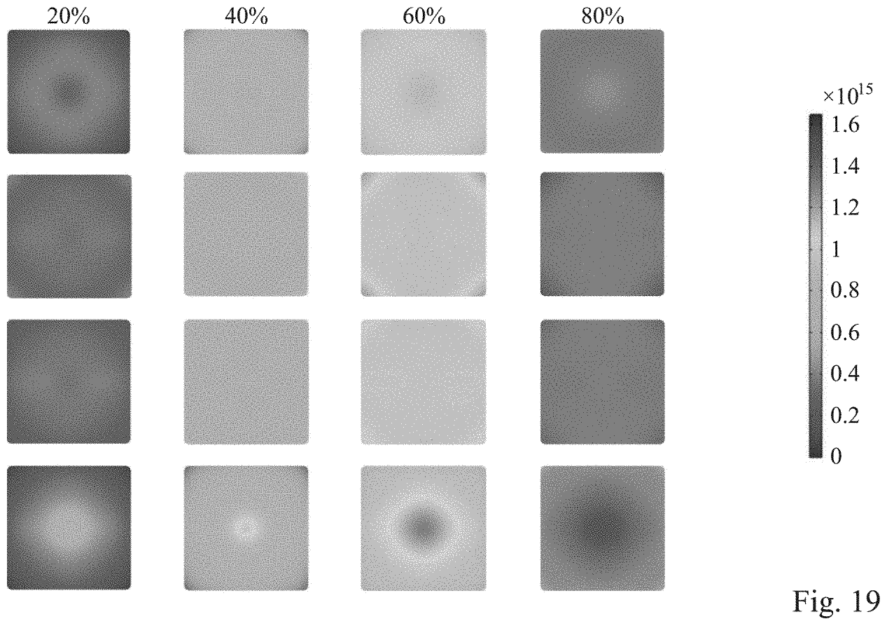

FIG. 18 shows CF₄ non-uniformities as functions of the degree of CF₄ saturation as the diffusing plates of the second example, the third example, the fourth example and the first comparison example diffusing CF₄. FIG. 19 shows a CF₄ diffusing status and the degree of CF₄ saturation as the diffusing plate of the second example, the third example, the fourth example and the first comparison example diffusing CF₄. As the holes of the diffusing plate are arranged in concentric rectangular patterns, the transportation uniformity of CF₄ is better than that of the diffusing plate P1 of the prior art where the holes are arranged in concentric circular patterns. However, the uniformities between the center of the substrate and corners of the substrate are still different, and an improvement thereof is still required. Hence, the diameters of the holes in different zones of the diffusing plate may be modified to increase the uniformity. ϕ1, ϕ2 and ϕ3 may be 0.8 mm, 1.8 mm and 1.8 mm of the second example, and a diameter relation thereof is similar to the first example. ϕ1, ϕ2 and ϕ3 may be 1.2 mm, 1.8 mm and 2.2 mm of the third example, ϕ1, ϕ2 and ϕ3 may be 1.2 mm, 1.8 mm and 2.0 mm of the fourth example, and therefore the diameter of the holes in the corners is larger than the diameter of the holes in the center. The hole positioning arrangement of the first comparison example is identical to that of the second example, but ϕ1, ϕ2 and ϕ3 may be 1.8 mm, 1.5 mm and 1.8 mm of the first comparison example. In simulation, the scale of the rectangular hole-configuring region of each of the diffusing plates of the second example, the third example, the fourth example and the first comparison example is 770 mm×770 mm, and a distance between the diffusing plate and a substrate having a scale of 640 mm×640 mm is 70 mm.

As shown in FIG. 18, the non-uniformity is lower as using the diffusing plates of the second example, the third example and the fourth example to diffuse CF₄, and the fourth example has the best overall performance on transport uniformity. Therefore, the etching non-uniformity may be reduced. In addition, as shown in FIG. 19, the second example, the third example, the fourth example and the first comparison example being arranged from the top to the bottom thereof, the uniformities of the center and the corners of the substrate are better as using the diffusing plates of the third example and the fourth example to diffuse CF₄, and the uniformity may be further improved as the diameters of the holes in the outer zone is larger than the diameters of the holes of the center zone.

The embodiments shown and described above are only examples. Therefore, many such details are neither shown nor described. Even though numerous characteristics and advantages of the present technology have been set forth in the foregoing description, together with details of the structure and function, the disclosure is illustrative only, and changes may be made in the detail, especially in matters of shape, size, and arrangement of the parts within the principles, up to and including the full extent established by the broad general meaning of the terms used in the claims. It will therefore be appreciated that the embodiments described above may be modified within the scope of the claims.

What is claimed is:

1. A diffusing plate, comprising:
a plate body comprising a rectangular hole-configuring region;
a plurality of holes arranged in the rectangular hole-configuring region and arranged concentrically to form a first to an N-th rectangular patterns from an inside to an outside sequentially, wherein scales of the first to the N-th rectangular patterns are incrementally increased, and N is a positive integer;
wherein one portion of the holes are located in an area near a center of the rectangular hole-configuring region, another portion of the holes are located in four corner areas of the rectangular hole-configuring region, each of the holes has a diameter, and the diameter of the one portion of the holes is smaller than the diameter of the another portion of the holes.

2. The diffusing plate of claim 1, wherein ΔSᵢ represents a side-length difference between an i-th rectangular pattern of the first to the N-th rectangular patterns and a neighboring one of the first to the N-th rectangular patterns adjacent thereto, ΔSᵢ is positive, i is an integer index representing each of the first to the N-th rectangular patterns and ranged between 1 to N, ΔSᵢ is equal to a side-length of the first rectangular pattern, and a condition of 3 mm≤ΔSᵢ≤50 mm is satisfied.

3. The diffusing plate of claim 2, wherein CIᵢ represents a circumferential hole distance between one of the holes that is located in the i-th rectangular pattern and a neighboring one of the holes adjacent thereto along a side-length direction of the i-th rectangular pattern, and a condition of 0.3×ΔSᵢ≤CIᵢ≤5×ΔSᵢ is satisfied.

4. The diffusing plate of claim 2, wherein the first to the N-th rectangular patterns are partitioned into a plurality of groups each indexed by an integer j ranged from 1 to J, each of the groups comprising an integer dⱼ of neighboring rectangular patterns, starting from an i_{min,j}-th to an i_{max,j}-th rectangular patterns, wherein i_{max,j}=i_{min,j}+dⱼ−1, the circumferential hole distances CIᵢ of the rectangular patterns of each of the groups are increased as the corresponding integer index i increases, the i_{min,j}-th to the i_{max,j}-th rectangular patterns belong to one of the groups, an i_{max,j}+1-th rectangular pattern belongs to another one of the groups adjacent thereto, the circumferential hole distance of the i_{max,j}+1-th rectangular pattern is smaller than the circumferential hole distance of the i_{max,j}-th rectangular pattern.

5. The diffusing plate of claim 4, wherein a condition of 4≤dⱼ≤N is satisfied.

6. The diffusing plate of claim 4, wherein the circumferential hole distance of a largest one of the rectangular patterns of one of the groups that is away from the first rectangular pattern is smaller than the circumferential hole distance of a largest one of the rectangular patterns of another one of the groups that is near the first rectangular pattern.

7. The diffusing plate of claim 2, wherein the side-length difference corresponding to the first to an M-th rectangular patterns is different from the side-length difference corresponding to an M+1-th to the N-th rectangular patterns, M is a positive integer, and M is smaller than N/2.

8. The diffusing plate of claim 1, wherein each of four corner points of each of the first to the N-th rectangular patterns comprises one of the holes.

9. The diffusing plate of claim 1, wherein the diffusing plate is configured for being employed in a panel-level packaging process, and the diffusing plate is electrically floating, grounded or connected to an alternating current source.

10. The diffusing plate of claim 1, wherein the rectangular hole-configuring region comprises a center zone, an outer zone and a first concentric circular zone between the center zone and the outer zone, the center zone covers the first to an M-th rectangular patterns, M is a positive integer, M is smaller than N/2, the area near the center of the rectangular hole-configuring region is located in the center zone, the outer zone covers the four corner areas of the rectangular hole-configuring region, ϕ1 represents the diameter of any one of the holes of the center zone, ϕ2 represents the diameter of any one of the holes of the first concentric circular zone, and a condition of ϕ1≤ϕ2 is satisfied.

11. The diffusing plate of claim 10, wherein, ϕ3 represents the diameter of any one of the holes of the outer zone, and a condition of 0.4 mm≤ϕ1<ϕ2<ϕ3≤2.5 mm is satisfied.

12. The diffusing plate of claim 10, wherein the first concentric circular zone has a first concentric circular boundary, D1 represents a first distance between the center of the rectangular hole-configuring region and the first concentric circular boundary, D0 represents a distance between the N-th rectangular pattern and the center of the rectangular hole-configuring region, and a condition of 0.7×D0≤D1≤D0 is satisfied.

13. The diffusing plate of claim 12, wherein the rectangular hole-configuring region further comprises a second concentric circular zone between the center zone and the first concentric circular zone, the second concentric circular zone has a second concentric circular boundary, D2 represents a second distance between the center of the rectangular hole-configuring region and the second concentric circular boundary, ϕ2′ represents the diameter of any one of the holes of the second concentric circular zone, ϕ3 represents the diameter of any one of the holes of the outer zone, and conditions of 0.3×D0≤D2≤0.8×D0 and ϕ1<ϕ2′≤ϕ2<ϕ3 are satisfied.

14. An etching equipment, comprising:
a chamber;
a gas inlet communicated with the chamber and configured for providing a processing gas; and
the diffusing plate of claim 1 disposed in the chamber and located under the gas inlet.

15. The etching equipment of claim 14, further comprising a substrate carrier disposed in the chamber and located under the diffusing plate, the substrate carrier comprising a rectangular effective processing region for containing at least one substrate, wherein a side-length of the N-th rectangular pattern of the diffusing plate is larger than a side-length of the rectangular effective processing region, and a ratio of the side-lengths thereof is ranged between 1.0 to 2.0.

16. A hole configuring method for a diffusing plate, comprising:
a hole-configuring region designing step, wherein a rectangular hole-configuring region of a plate body of the diffusing plate is defined; and
a hole configuring step, wherein positions of a plurality of holes are arranged in the rectangular hole-configuring region, the holes are arranged concentrically to form a first to an N-th rectangular patterns from an inside to an outside sequentially, scales of the first to the N-th rectangular patterns are incrementally increased, N is a positive integer, one portion of the holes are located in an area near a center of the rectangular hole-configuring region, another portion of the holes are located in four corner areas of the rectangular hole-configuring region, each of the holes has a diameter, the diameter of the one portion of the holes is smaller than the diameter of the another portion of the holes, ΔSᵢ represents a side-length difference between an i-th rectangular pattern of the first to the N-th rectangular patterns and a neighboring one of the first to the N-th rectangular patterns adjacent thereto, ΔSᵢ is positive, CIᵢ represents a circumferential hole distance between one of the holes that is located in the i-th rectangular pattern and a neighboring one of the holes adjacent thereto along a side-length direction of the i-th rectangular pattern, i is an integer index representing each of the first to the N-th rectangular patterns and ranged between 1 to N, ΔSᵢ is equal to a side-length of the first rectangular pattern, and the hole configuring step comprises:
defining an actual circumferential hole distance upper-limit range and an actual circumferential hole distance lower-limit range;
partitioning the first to the N-th rectangular patterns into a plurality of groups, each of the groups containing an integer dⱼ of neighboring rectangular patterns, staring from an i_{min,j}-th rectangular pattern to an i_{max,j}-th rectangular pattern, wherein i_{max,j}=i_{min,j}+dⱼ−1; and
configuring the circumferential hole distance CIᵢ of the i_{min,j}-th rectangular patterns of each of the groups to fall within the actual circumferential hole distance lower-limit range, configuring the circumferential hole distance CIᵢ of the i_{max,j}-th rectangular pattern of each of the groups to fall within the actual circumferential hole distance upper-limit range, configuring the circumferential hole distances CIᵢ of the i_{min,j}-th to the i_{max,j}-th rectangular patterns of each of the groups to be monotonously increased as the corresponding integer index i increases, wherein an i_{max,j}+1-th rectangular pattern belongs to another one of the groups adjacent thereto, and the circumferential hole distance of the i_{max,j}+1-th rectangular pattern is smaller than the circumferential hole distance of the i_{max,j}-th rectangular pattern.

17. The hole configuring method of claim 16, wherein in the hole configuring step for each of the groups with the index j,
$${CI}_{i} = ( \frac{( i - {i}_{min , j} ) Mod {d}_{j}}{( {d}_{j} - 1 )} ) \times a Max {CI}_{i} + ( 1 - \frac{( i - {i}_{min , j} ) Mod {d}_{j}}{( {d}_{j} - 1 )} ) \times a Min {CI}_{i}$$
is used to calculate the circumferential hole distance of the i-th rectangular pattern, aMaxCIᵢ represents a value in the actual circumferential hole distance upper-limit range corresponding to the i-th rectangular pattern, and aMinCIᵢ represents a value in the actual circumferential hole distance lower-limit range corresponding to the i-th rectangular pattern.

18. The hole configuring method of claim 16, wherein in the hole configuring step, ΔSᵢ is defined first.

19. The hole configuring method of claim 16, wherein in the hole configuring step, the actual circumferential hole distance upper-limit range is ranged between 18 mm to 22 mm, and the actual circumferential hole distance lower-limit range is ranged between 12 mm to 14 mm.
